(19) United States
(12) Patent Application Publication
(10) Pub. No.: US 2026/0142134 A1
(43) Pub. Date: May 21, 2026

(54) SEGMENTED FOCUS RING FOR PLASMA SEMICONDUCTOR PROCESSING AND PROCESSING TOOL CONFIGURED TO USE The SEGMENTED FOCUS RING

(71) Applicant: BEIJING NAURA MICROELECTRONICS EQUIPMENT CO., LTD., Beijing (CN)

(72) Inventors: Yulin PENG, Beijing (CN); Jinrong ZHAO, Beijing (CN)

(21) Appl. No.: 18/698,957

(22) PCT Filed: Aug. 25, 2022
(86) PCT No.: PCT/CN2022/114823

§ 371 Date: Apr. 5, 2024

(51) Int. Cl. H01J 37/32

(52) U.S. Cl. CPC H01J 37/32642; H01J 2237/1502

(57) ABSTRACT

The present disclosure relates to plasma semiconductor processes and processing tools for such processes. In one example, a processing tool includes a chamber, a substrate support, and a focus ring (FR) movement assembly. The substrate support is disposed in the chamber and has a support surface. The FR movement assembly is disposed in the chamber and includes a frame and segment supports mechanically coupled to the frame. Each segment support is configured to support a respective discrete segment of a focus ring. The FR movement assembly is configured to support the discrete segments disposed laterally encircling the support surface. The FR movement assembly is further configured to (i) translate the segment supports in directions parallel to radial directions in a plane of and from a center of the support surface and/or (ii) tilt the segment supports around respective axes parallel to the support surface.

### BACKGROUND

Plasma processing has become ubiquitous in the semiconductor industry. Plasma semiconductor processes have been used to etch materials, deposit materials, or the like. Such plasma processes have been found to have improved processing qualities or resulting characteristics on the semiconductor substrate. For example, plasma enhanced chemical vapor deposition (PECVD) has been found to have advantages over previous chemical vapor deposition (CVD) processes, including lower deposition temperature, increased material purity, and improved step coverage. However, introduction of plasma has resulted in various challenges.

### SUMMARY

One embodiment of the present disclosure provides a processing tool for semiconductor processing. The processing tool includes a chamber, a substrate support, and a focus ring movement assembly. The chamber has an internal volume within the chamber. The substrate support is disposed in the chamber. The substrate support has a support surface configured to support a semiconductor substrate. The focus ring movement assembly is disposed in the chamber. The focus ring movement assembly includes a frame and a plurality of segment supports mechanically coupled to the frame. Each segment support of the plurality of segment supports is configured to support a respective discrete segment of a focus ring. The focus ring includes a plurality of discrete segments. The focus ring movement assembly is configured to support the plurality of discrete segments disposed laterally encircling the support surface. The focus ring movement assembly is configured to translate the plurality of segment supports in respective first directions. Each first direction of the respective first directions is parallel to a respective radial direction that is in a plane of the support surface and from a center of the support surface.

Another embodiment of the present disclosure provides a processing tool for semiconductor processing. The processing tool includes a chamber, a substrate support, and a focus ring movement assembly. The chamber has an internal volume within the chamber. The substrate support is disposed in the chamber. The substrate support has a support surface configured to support a semiconductor substrate. The focus ring movement assembly is disposed in the chamber. The focus ring movement assembly includes a frame and a plurality of segment supports mechanically coupled to the frame. Each segment support of the plurality of segment supports is configured to support a respective discrete segment of a focus ring. The focus ring includes a plurality of discrete segments. The focus ring movement assembly is configured to support the plurality of discrete segments disposed laterally encircling the support surface. The focus ring movement assembly is configured to tilt the plurality of segment supports around respective axes, and each axis of the respective axes is parallel to the support surface.

Another embodiment of the present disclosure provides a method for semiconductor processing. The method includes moving a plurality of ring segments of a focus ring to respective positions relative to a semiconductor substrate. The semiconductor substrate is disposed on a support surface of a substrate support. The substrate support is disposed in a chamber of a processing tool. The plurality of ring segments of the focus ring laterally encircle the semiconductor substrate. Moving the plurality of ring segments includes translating the plurality of ring segments in respective first directions. Each first direction of the respective first directions is parallel to a respective radial direction that is in a plane of the support surface and from a center of the support surface. The method includes generating plasma in a processing volume of the chamber. The semiconductor substrate is exposed to the plasma while the plurality of ring segments are at the respective positions relative to the semiconductor substrate.

Another embodiment of the present disclosure provides a method for semiconductor processing. The method includes moving a plurality of ring segments of a focus ring to respective positions relative to a semiconductor substrate. The semiconductor substrate is disposed on a support surface of a substrate support. The substrate support is disposed in a chamber of a processing tool. The plurality of ring segments of the focus ring laterally encircle the semiconductor substrate. Moving the plurality of ring segments includes tilting the plurality of ring segments around respective axes. Each axis of the axes is parallel to the support surface. The method includes generating plasma in a processing volume of the chamber. The semiconductor substrate is exposed to the plasma while the plurality of ring segments are at the respective positions relative to the semiconductor substrate.

Another embodiment of the present disclosure provides a method for semiconductor processing. The method includes performing plasma semiconductor process having first process conditions on a first plurality of substrates using a processing tool. A plurality of discrete segments of a focus ring laterally encircle a substrate during the plasma semiconductor process. The first process conditions correspond to respective positions of the plurality of discrete segments disposed at respective first radial distances from a substrate during the plasma semiconductor process on the first plurality of substrates. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristics are formed by the plasma semiconductor process. The method includes, by a processor-based system, determining second process conditions to be applied while performing the plasma semiconductor process on a second plurality of substrates based on the first characteristics and the second characteristics. The second process conditions correspond to respective positions of the plurality of discrete segments disposed at respective second radial distances from a substrate during the plasma semiconductor process on the second plurality of semiconductor substrates. The method includes performing the plasma semiconductor process having the second process conditions on the second plurality of substrates using the processing tool.

Another embodiment of the present disclosure provides a method for semiconductor processing. The method includes performing plasma semiconductor process having first process conditions on a first plurality of substrates using a processing tool. A plurality of discrete segments of a focus ring laterally encircle a substrate during the plasma semiconductor process. The first process conditions correspond to respective positions of the plurality of discrete segments disposed at respective tilt angles relative to a top surface of a substrate during the plasma semiconductor process on the first plurality of substrates. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristics are formed by the plasma semiconductor process. The method includes by a processor-based system, determining second process conditions to be applied while performing the plasma semiconductor process on a second plurality of substrates based on the first characteristics and the second characteristics. The second process conditions correspond to respective positions of the plurality of discrete segments disposed at respective tilt angles relative to a top surface of a substrate during the plasma semiconductor process on the second plurality of substrates. The method includes performing the plasma semiconductor process having the second process conditions on the second plurality of substrates using the processing tool.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

So that the above recited features can be understood in detail, reference is made to the following detailed description taken in conjunction with the accompanying drawings.

FIG. 1 is a schematic view of a processing tool for semiconductor processing according to some embodiments of the present disclosure.

FIGS. 2A and 2B are a layout view and cross-sectional view, respectively, of a segmented focus ring according to some embodiments of the present disclosure.

FIGS. 3A and 3B are a layout view and cross-sectional view, respectively, of a segmented focus ring according to some embodiments of the present disclosure.

FIG. 4 is a layout view of a segmented focus ring illustrating lateral, radial translation of focus ring segments according to some embodiments of the present disclosure.

FIG. 5 is a simplified cross-sectional view of a focus ring radial translation assembly according to some embodiments of the present disclosure.

FIG. 6 is a perspective view of a focus ring radial translation assembly according to some embodiments of the present disclosure.

FIGS. 7 and 8 illustrate lateral, radial translation of focus ring segments by the focus ring radial translation assembly of FIGS. 5 and 6.

FIGS. 9 and 10 illustrate how gaps between focus ring segments and an edge of a semiconductor substrate can contribute to plasma control according to some embodiments of the present disclosure.

FIG. 11 is a cross-sectional view of a focus ring segment of a segmented focus ring illustrating tilting of the focus ring segment according to some embodiments of the present disclosure.

FIG. 12 is a simplified cross-sectional view of a focus ring tilt assembly according to some embodiments of the present disclosure.

FIG. 13A is a perspective view of a focus ring tilt assembly according to some embodiments of the present disclosure.

FIG. 13B is a perspective view of a portion of the focus ring tilt assembly of FIG. 13A according to some embodiments of the present disclosure.

FIGS. 14 and 15 illustrate tilting of the focus ring segments by the focus ring tilt assembly of FIG. 12.

FIGS. 16 and 17 illustrate how tilt of focus ring segments can contribute to plasma control according to some embodiments of the present disclosure.

FIG. 18 illustrates a focus ring movement assembly that includes a focus ring radial translation sub-assembly and a focus ring tilt sub-assembly according to some embodiments of the present disclosure.

FIGS. 19, 20, and 21 are simplified cross-sectional views of respective focus ring movement assemblies that include a focus ring vertical translation sub-assembly according to some embodiments of the present disclosure.

FIGS. 22 and 23 illustrate how vertical translation of focus ring segments can contribute to plasma control according to some embodiments of the present disclosure.

FIG. 24 is a schematic of a radio frequency (RF) power system of the processing tool of FIG. 1 according to some embodiments of the present disclosure.

FIG. 25 is a schematic of an RF power system that may be implemented with the processing tool of FIG. 1 according to some embodiments of the present disclosure.

FIG. 26 is a processor-based system according to some embodiments of the present disclosure.

FIG. 27 is a flow chart of a method of semiconductor processing according to some embodiments of the present disclosure.

FIG. 28 is a flow chart of a method for semiconductor processing according to some embodiments of the present disclosure.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to plasma semiconductor processes and to components and processing tools for plasma semiconductor processes. Some embodiments of the present disclosure described herein include a segmented focus ring that comprises multiple discrete focus ring segments. Generally, the focus ring segments can be translated in respective lateral, radial directions and/or tilted to respective tilt angles. Additionally, in some embodiments of the present disclosure, the focus ring segments can be translated in respective vertical directions. Moving and/or positioning the focus ring segments can contribute to control of plasma at an edge of a semiconductor substrate. Various other examples described herein include a processing tool including a focus ring movement assembly that is configured to move and/or position focus ring segments. Further, other examples described herein include a method of semiconductor processing using such segmented focus ring and processing tool, for example. Further examples include a method for semiconductor processing for determining positions of focus ring segments to be implemented in subsequent processing of semiconductor substrates based on results of previous processing of semiconductor processing.

Additionally, in some embodiments of the present disclosure, focus ring segments may include respective electrodes on which respective voltages, such as radio frequency (RF) signals, may be applied. In some embodiments of the present disclosure, focus ring segments may include respective heating elements on which respective voltages may be applied. A processing tool may include components to apply such voltages on the focus ring segments. Plasma semiconductor process may include applying such a voltage on the focus ring segments.

Plasma non-uniformity in a semiconductor process can result in defective integrated circuit (IC) dies being manufactured. Plasma non-uniformity has been observed between a center of a semiconductor substrate (e.g., a wafer) and proximate an edge of the semiconductor substrate. Since a significant number of IC dies are manufactured proximate an edge of a semiconductor substrate, plasma non-uniformity at the edge of the semiconductor substrate can result in a significant loss of yield.

Structural differences at the edge of a semiconductor substrate compared to the center of the semiconductor substrate can contribute to plasma non-uniformity between a center and an edge of the semiconductor substrate. For example, at the edge of the semiconductor substrate, the structure that contains or defines plasma may be different than at the center of the semiconductor substrate. At the center, the plasma is contained or defined by a flat, lateral surface of the semiconductor surface, whereas the edge with its vertical side is structurally different from the flat, lateral surface. A focus ring encircling the semiconductor substrate may be used to mitigate such a structural difference; however, a gap may exist between the focus ring and the semiconductor substrate due to manufacturing tolerances. The plasma sheath of the plasma may bend around the edge into the gap, which can lead to ion bombardment of the semiconductor substrate near the edge that is at an angle different than at the center of the semiconductor substrate.

Further, the physical structure of the processing tool can further determine, at least in part, the electromagnetic field used to generate the plasma. The structure of the electrodes between which the plasma is generated can determine the electromagnetic field. At a center of an electrode, the electromagnetic field may be modeled as generated from an infinite plane, with no or little edge effects. Near an edge of the electrode, edge effects become more pronounced, which can reduce and/or change the directionality of the electromagnetic field. As a result, the plasma density can be different at an edge of the semiconductor substrate compared to the center of the substrate. Further, the edge of the electrode is nearer to a wall of the chamber of the processing tool, which can create a low resistivity electromagnetic loop that can result in plasma density and ion energy difference between the center and edge.

Some embodiments of the present disclosure can address and/or mitigate some of these challenges related to plasma semiconductor process. By adjusting positions of the focus ring segments, the plasma sheath may be adjusted to cause more uniform angles of ion bombardment at the edge relative to the center of the semiconductor substrate. Additionally, by applying a voltage to electrodes of the focus ring, the electromagnetic field can be locally controlled to promote plasma uniformity, or by applying a voltage to heating elements of the focus ring, energy of the plasma can be locally controlled to promote plasma uniformity. Other advantages or benefits can be achieved using various aspects described herein.

For brevity and convenience, similar components shown in a figure may be referred to, either individually or collectively, by a same base reference numeral. In the figure, instances of such components may be labeled with the base reference numeral with a respective instance identifier (in the form of “-#”) appended thereto. For example, the description may refer to x number of widgets ZZZ, where instances in the figure are labeled as ZZZ-1, ZZZ-2, . . . ZZZ-x. Reference to a specific instance of a component in the description includes reference to the base reference numeral and the corresponding instance identifier (e.g., instance of widget ZZZ-2).

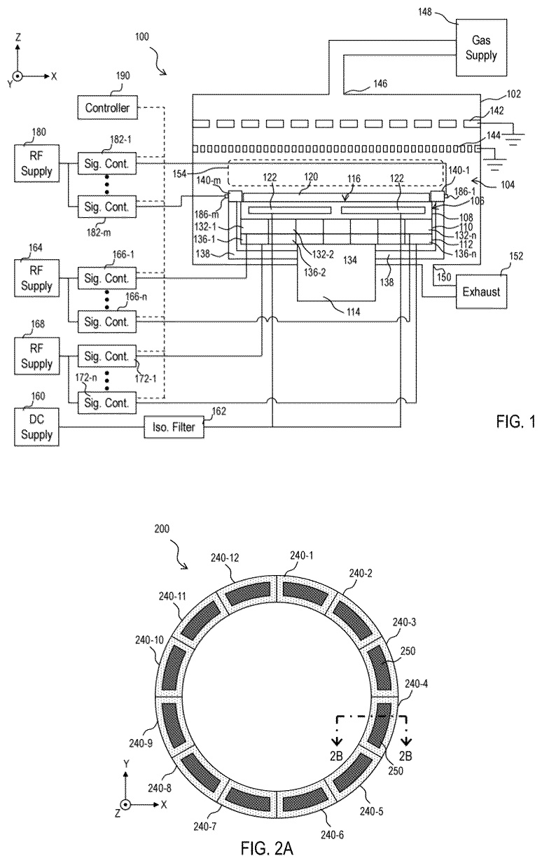

FIG. 1 is a schematic view of a processing tool 100 for semiconductor processing according to some embodiments of the present disclosure. FIG. 1 includes an X-Y-Z axis for ease of describing various orientations, and such axis is reproduced according to orientation in other figures. The processing tool 100 in FIG. 1 is illustrated simplistically so as to not obscure various aspects described herein. A person having ordinary skill in the art will readily understand other aspects of the processing tool 100. The processing tool 100 is shown as a capacitively coupled plasma (CCP) processing tool in this example. In other examples, the processing tool 100 can be configured as an inductively coupled plasma (ICP) processing tool, electron cyclotron resonance (ECR) processing tool, or another processing tool. A person having ordinary skill in the art will readily understand aspects described herein as being applicable to such other processing tools. The processing tool 100 can be for performing plasma semiconductor process, such as sputtering, physical vapor deposition (PVD), modified double plasma (MDP), plasma-enhanced chemical vapor deposition (PECVD), ion beam etching (IBE), reactive ion etching (RIE), and other semiconductor processes.

The processing tool 100 includes a chamber 102. The chamber 102 has an internal volume 104 that is defined by inner walls of the chamber 102. The processing tool 100 includes a substrate support 106 disposed in the internal volume 104 of the chamber 102. The substrate support 106 includes an electrostatic chuck (ESC) 108, a mid-plate 110, and a baseplate 112. In the illustrated configuration, the mid-plate 110 is disposed over and on the baseplate 112, and the ESC 108 is disposed over and on the mid-plate 110. The substrate support 106 is disposed on and is supported by a pedestal 114. The baseplate 112 is disposed over and on the pedestal 114.

The substrate support 106 has a support surface 116 that is configured to support a semiconductor substrate 120 during a semiconductor process. During a semiconductor process, a semiconductor substrate 120 is disposed on the support surface 116 of the substrate support 106. The support surface 116 is a top surface of the ESC 108 in the illustrated example. The support surface 116, in the illustration of FIG. 1, is in an x-y plane.

The ESC 108 includes chucking electrodes 122. The chucking electrodes 122 are configured to have a direct current (DC) voltage applied thereto for chucking the semiconductor substrate 120 on the support surface 116. The ESC 108 can include a dielectric material that coats the chucking electrodes 122 to provide electrical isolation from direct contact between the chucking electrodes 122. The dielectric material can be or include any non-conductive material, such as aluminum oxide (Al2O3), yttrium oxide (Y2O3), silicon oxide (SiO2), the like, or a combination thereof. In some embodiments of the present disclosure, the ESC 108 may include resistive heating elements configured to have an electrical current flow therethrough, which can generate thermal energy that is conducted to the semiconductor substrate 120.

The mid-plate 110 includes n number of RF electrodes 132. The RF electrodes 132 are configured to have a voltage (e.g., an RF signal) applied thereto to generate and/or control plasma. The RF electrodes 132 can have any arrangement and any number of electrodes. By including multiple RF electrodes 132, localized control of plasma in the chamber 102 may be achieved. The RF electrodes 132 may have a dielectric material thereon to provide electrical isolation from direct electrical contact of the RF electrodes 132 to other components. In some embodiments of the present disclosure, the mid-plate 110 includes fluid channels that are configured to have a fluid (e.g., a liquid) flowing therethrough to remove and dissipate thermal energy from the semiconductor substrate 120. The fluid channels may be referred to as a cooler.

The baseplate 112 includes n number of bias electrodes 136. The bias electrodes 136 are configured to have a bias voltage (e.g., an RF signal) applied thereto to promote drivability of the RF electrodes 132. The bias electrodes 136 can have any arrangement and any number of electrodes. In some embodiments of the present disclosure, the number and arrangement of the bias electrodes 136 corresponds to the number and arrangement of the RF electrodes 132. In some embodiments of the present disclosure, the baseplate 112 has one bias electrode 136. The bias electrodes 136 may have a dielectric material thereon to provide electrical isolation from direct electrical contact of the bias electrodes 136 to other components.

The processing tool 100 includes a focus ring movement assembly. As generically illustrated in FIG. 1, the focus ring movement assembly includes a frame 138. The frame 138 laterally projects from the pedestal 114 in the illustrated example. The frame 138 is configured to support a segmented focus ring laterally encircling the semiconductor substrate 120 disposed on the support surface 116. The segmented focus ring, as shown in FIG. 1, includes m number of focus ring segments 140 that, as supported by the focus ring movement assembly, laterally encircle the semiconductor substrate 120. As detailed subsequently, in various examples, the frame 138 can be moveable or fixed, and further, may be separated from the substrate support 106 or attached to, fixed to, and/or integral with the substrate support 106 (e.g., the ESC 108). The focus ring movement assembly, in various examples, is configured (i) to laterally, radially translate the focus ring segments 140 (e.g., in an x-y plane parallel to the support surface 116), (ii) to tilt the focus ring segments 140 (e.g., in respective angles relative to an axis normal to the support surface 116), or (iii) a combination thereof. The focus ring movement assembly, in various examples, may further be configured to vertically translate the focus ring segments 140 (e.g., in a z-direction normal to the support surface 116). Additional details of the focus ring movement assembly are described subsequently.

The processing tool 100 further includes a gas distribution plate 142 and a gas showerhead 144 disposed in the internal volume 104 of the chamber 102. The gas distribution plate 142 has openings therethrough, and the gas showerhead 144 has openings therethrough. The gas distribution plate 142 and the gas showerhead 144 are electrically coupled to a ground node (e.g., are electrically grounded). The chamber 102 has a gas inlet 146 fluidly coupled to a gas supply system 148, and has a gas outlet 150 fluidly coupled to an exhaust system 152. The gas distribution plate 142 and gas showerhead 144 are positioned in the internal volume 104 of the chamber 102 relative to the substrate support 106 such that, during a semiconductor process, a gas flows from the gas supply system 148, through the gas inlet 146, through the openings through the gas distribution plate 142, and then through the openings through the gas showerhead 144 to a processing volume 154 in the internal volume 104. The processing volume 154 is disposed between the gas showerhead 144 and the substrate support 106 and is generally where plasma is generated (using the gas flowed into the processing volume 154) during a semiconductor process. A semiconductor substrate 120 disposed on the support surface 116 of the substrate support 106 is exposed to plasma in the processing volume 154 during the semiconductor process. The gas can then flow through the gas outlet 150 to the exhaust system 152 to be exhausted out of the internal volume 104 of the chamber 102.

The processing tool 100 includes a DC power supply 160 and an isolation filter 162. The DC power supply 160 is configured to generate and output a DC voltage. Output nodes (e.g., a positive output node and a negative output node) of the DC power supply 160 are electrically coupled to input nodes of the isolation filter 162, and output nodes of the isolation filter 162 are electrically coupled to respective chucking electrodes 122. The isolation filter 162 may be, for example, a low pass filter. The DC power supply 160 can be selectively turned on and off to chuck and release a semiconductor substrate 120.

The processing tool 100 includes an RF power supply 164 and n number of signal control circuits 166. The RF power supply 164 may include an RF power generator and an RF matching network, and is configured to generate and output an RF voltage (e.g., RF signal, which may be a continuous RF signal and/or a pulsed RF signal) on an output node of the RF power supply 164. The output node of the RF power supply 164 is electrically coupled to respective input nodes of the signal control circuits 166. The signal control circuits 166 are individually controllable to generate a respective adjusted RF voltage based on the RF voltage received from the RF power supply 164. The adjusted RF voltage generated by the respective signal control circuit 166 may have an adjusted amplitude (e.g., by a gain of the signal control circuit 166, which may have a magnitude greater than, equal to, or less than 1) of the received RF voltage and/or may have a phase offset from the received RF voltage. The gain and/or phase offset may be selectable from a set of gains and/or phase offsets, respectively, that the signal control circuit 166 is configured to implement. Each signal control circuit 166 has an output node that is electrically coupled to a corresponding RF electrode 132 of the mid-plate 110. Each signal control circuit 166 is configured to output the respective adjusted RF voltage on the output node, and hence, the adjusted RF voltage can be applied to the respective RF electrode 132. The RF voltage output by each signal control circuit 166 can be used for generating and/or controlling plasma in the processing volume 154 (e.g., locally generating and/or controlling).

The processing tool 100 includes an RF power supply 168 and n number of signal control circuits 172. The RF power supply 168 may include an RF power generator and an RF matching network, and is configured to generate and output an RF voltage (e.g., RF signal, which may be a continuous RF signal and/or a pulsed RF signal) on an output node of the RF power supply 168. The output node of the RF power supply 168 is electrically coupled to respective input nodes of the signal control circuit 172. Like the signal control circuits 166, the signal control circuits 172 are individually controllable to generate an adjusted RF voltage based on the RF voltage received from the signal control circuit 172. The adjusted RF voltage generated by the respective signal control circuit 172 may have an adjusted amplitude (e.g., by a gain of the signal control circuit 172, which may have a magnitude greater than, equal to, or less than 1) of the received RF voltage and/or may have a phase offset from the received RF voltage. The gain and/or phase offset may be selectable from a set of gains and/or phase offsets, respectively, that the respective signal control circuit 172 is configured to implement. Each signal control circuit 172 has an output node that is electrically coupled to a corresponding bias electrode 136 of the baseplate 112. In examples where the baseplate 112 has a single bias electrode 136, a signal control circuit 172 similarly has an output node electrically coupled to the single bias electrode 136 (e.g., additional signal control circuits 172 may be omitted).

The baseplate 112, in this example, may be strongly capacitively coupled to the RF electrodes 132 in the mid-plate 110. Hence, according to some embodiments of the present disclosure, the baseplate 112 is biased by the RF voltages output by the signal control circuits 172 to increase drivability of the RF electrodes 132 to generate plasma. The signal control circuits 172, in operation, output respective RF voltages that have respective target amplitudes and respective target phase offsets relative to the RF voltage applied to the corresponding RF electrode 132. Having such RF voltages applied to the bias electrodes 136 of the baseplate 112 permits increased drivability of the RF electrodes 132 to generate and control plasma.

The processing tool 100 includes an RF power supply 180 and m number of signal control circuits 182. The RF power supply 180 may include an RF power generator and an RF matching network, and is configured to generate and output an RF voltage (e.g., RF signal, which may be a continuous RF signal and/or a pulsed RF signal) on an output node of the RF power supply 180. The output node of the RF power supply 180 is electrically coupled to respective input nodes of the signal control circuits 182. The signal control circuits 182 are each individually controllable to generate an adjusted RF voltage based on the RF voltage received from the RF power supply 180. The adjusted RF voltage generated by the respective signal control circuit 182 may have an adjusted amplitude (e.g., by a gain of the signal control circuit 182, which may have a magnitude greater than, equal to, or less than 1) of the received RF voltage and/or may have a phase offset from the received RF voltage. The gain and/or phase offset may be selectable from a set of gains and/or phase offsets, respectively, that the respective signal control circuit 182 is configured to implement. Each signal control circuit 182 has an output node that is electrically coupled to an external electrical connector 186 of a corresponding focus ring segment 140 of the segmented focus ring. The respective signal control circuit 182 is configured to output the adjusted RF voltage on the output node, and hence, the adjusted RF voltage can be applied to the respective focus ring segment 140. The RF voltages output by the signal control circuits 182 can be used for controlling plasma in the processing volume 154 proximate an edge of the semiconductor substrate 120.

The processing tool 100 includes a controller 190. The controller 190 can be or include any processor-based system, which may be or include a hardened processor architecture, a soft processor (e.g., implemented on programmable fabric of a field programmable gate array (FPGA)), or a combination thereof. For example, the controller 190 can be or include a computer, a server, a programmable logic controller (PLC), the like, or a combination thereof. The controller 190 can control operation of the processing tool 100 and can be programmed to implement operations of the processing tool 100 as described herein. Among other things, the controller 190 is communicatively coupled to the signal control circuits 166, 172, 182. The controller 190 can be programmed to implement various setpoints for controlling the signal control circuits 166, 172, 182. The setpoints can be implemented in the signal control circuits 166, 172, 182 to implement and/or selectively configure the respective control circuit to achieve a corresponding gain and/or phase offset.

Although the segmented focus ring (comprising the focus ring segments 140) in reference to the processing tool 100 of FIG. 1 is described as implemented to control plasma in the chamber 102, the segmented focus ring may be implemented in other processing tools, such as an ICP processing tool. Aspects described herein can be applicable to other tools and configurations to control plasma.

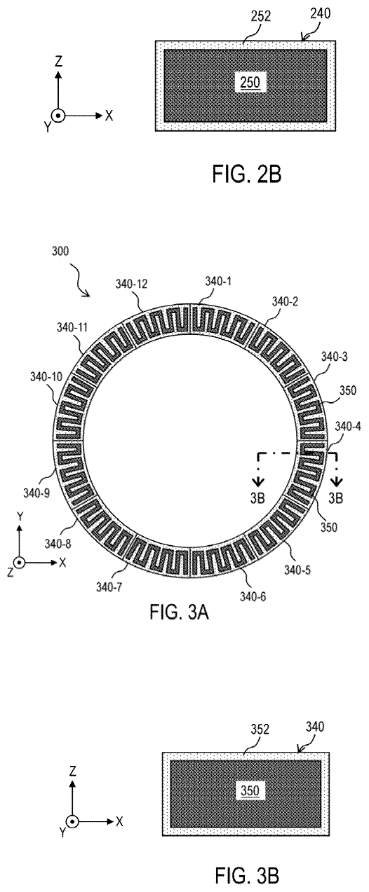

FIGS. 2A and 2B are a layout view and cross-sectional view, respectively, of a segmented focus ring 200 according to some embodiments of the present disclosure. FIG. 2A shows the cross-section 2B-2B that is illustrated in FIG. 2B. The segmented focus ring 200 includes twelve focus ring segments 240 (e.g., corresponding to focus ring segments 140 in FIG. 1) in this example. In other examples, other numbers of focus ring segments may be implemented.

Each focus ring segment 240 includes a respective electrode 250. The electrode 250 of the focus ring segment 240 is electrically coupled to the respective external electrical connector 186, which is configured to be electrically coupled to a signal control circuit 182. A dielectric material 252 coats the electrode 250. The dielectric material 252 can provide electrical isolation of the electrode 250 from direct electrical contact with other components, including electrodes 250 of neighboring focus ring segments 240. Example dielectric material 252 includes any non-conductive material, such as aluminum oxide (Al2O3), yttrium oxide (Y2O3), silicon oxide (SiO2), the like, or a combination thereof. The electrode 250 can be formed of any conductive material (e.g., a metal), such as aluminum (Al), copper (Cu), titanium (Ti), tungsten (W), the like, or a combination thereof.

Respective RF voltages can be applied to the electrodes 250 of the focus ring segments 240 to control an electromagnetic field proximate an edge of the semiconductor substrate 120 in plasma semiconductor process. By using multiple focus ring segments 240, the electromagnetic field can be controlled locally proximate to each focus ring segment 240. By controlling the electromagnetic field, plasma at the edge of the semiconductor substrate 120 can be locally controlled, which may promote plasma uniformity.

FIGS. 3A and 3B are a layout view and cross-sectional view, respectively, of a segmented focus ring 300 according to some embodiments of the present disclosure. FIG. 3A shows the cross-section 3B-3B that is illustrated in FIG. 3B. The segmented focus ring 300 includes twelve focus ring segments 340 (e.g., corresponding to focus ring segments 140 in FIG. 1) in this example. In other examples, other numbers of focus ring segments may be implemented.

Each focus ring segment 340 includes a respective resistive heating element 350. The resistive heating element 350 of the focus ring segment 340 is electrically coupled between two nodes of the respective external electrical connector 186, which is configured to be electrically coupled to a signal control circuit 182. The resistive heating element 350, as electrically coupled between two nodes of the respective external electrical connector 186, is configured to have an electrical current flow through the resistive heating element 350 to generate thermal energy. The resistive heating element 350 is arranged in a serpentine arrangement in the respective focus ring segment 340. A dielectric material 352 coats the resistive heating element 350. The dielectric material 352 can provide electrical isolation of the resistive heating element 350 from direct electrical contact with other components, including resistive heating element 350 of neighboring focus ring segments 340.

Generating thermal energy by the focus ring segments 240 can change the energy of plasma proximate an edge of the semiconductor substrate 120 in plasma semiconductor process. An RF voltage applied to a resistive heating element 350 of a focus ring segment 340 can increase the energy of the plasma proximate that focus ring segment 340. By using multiple focus ring segments 340, the thermal energy of the plasma can be controlled locally proximate to each focus ring segment 340. By controlling the thermal energy, the plasma at the edge of the semiconductor substrate 120 can be locally controlled, which may promote plasma uniformity.

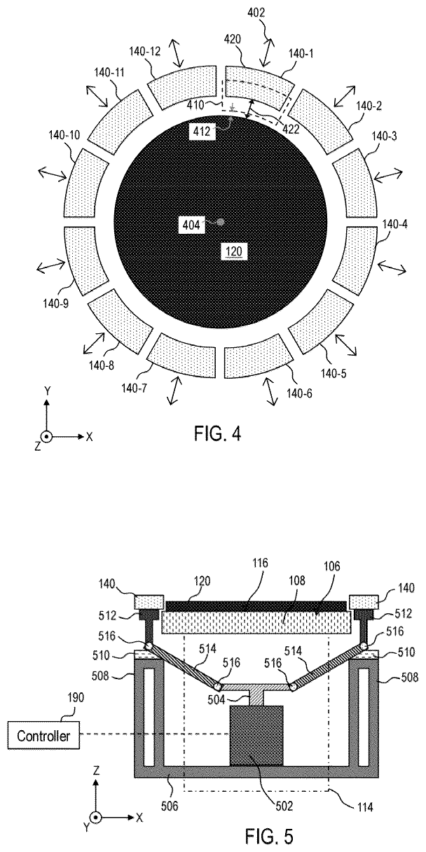

In some embodiments of the present disclosure, the focus ring movement assembly is a focus ring radial translation assembly that is configured to laterally, radially translate the focus ring segments 140 (e.g., in an x-y plane parallel to the support surface 116). FIG. 4 is a layout view of a segmented focus ring (comprising focus ring segments 140) illustrating lateral, radial translation of the focus ring segments 140 according to some embodiments of the present disclosure. Each focus ring segment 140 may be translated along a respective lateral, radial direction 402 from a center 404 of the segmented focus ring (e.g., in an x-y plane parallel to the support surface 116 and/or a top surface of the semiconductor substrate 120). Each focus ring segment 140 may be positioned in a proximal position 410 that is most proximate to the support surface 116 and/or the semiconductor substrate 120. In the proximal position 410, the respective focus ring segment 140 can have a smallest lateral, radial gap 412 between an inner sidewall surface of the respective focus ring segment 140 and an edge of the semiconductor substrate 120. Each focus ring segment 140 may be positioned in a distal position 420 that is most distal from the support surface 116 and/or the semiconductor substrate 120. In the distal position 420, the respective focus ring segment 140 can have a greatest lateral, radial gap 422 between the inner sidewall surface of the respective focus ring segment 140 and the edge of the semiconductor substrate 120. The focus ring radial translation assembly can laterally, radially translate the focus ring segments to any respective position from the respective proximal position 410 to the distal position 420.

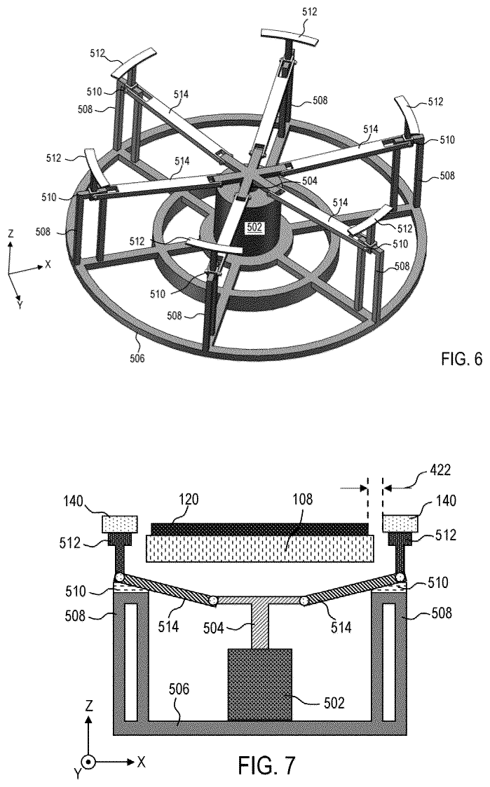

FIG. 5 is a simplified cross-sectional view of the focus ring radial translation assembly, and FIG. 6 is a perspective view of the focus ring radial translation assembly, according to some embodiments of the present disclosure. The focus ring radial translation assembly in this example is configured to support and move six focus ring segments 140. In other examples, the focus ring radial translation assembly may be configured to support any number of focus ring segments 140. A semiconductor substrate 120, focus ring segments 140, ESC 108, pedestal 114, and controller 190 are shown for context in FIG. 5.

The focus ring radial translation assembly includes a motor 502 having a drive shaft 504, a frame 506 having vertical brackets 508, lateral translation guide tracks 510, segment supports 512, and linkages 514. The motor 502 is configured to vertically project and retract the drive shaft 504 (e.g., along a z-direction). In some embodiments of the present disclosure, the motor 502 is a stepper motor (e.g., a helical stepper motor), a pneumatic motor, or a linear actuator/drive motor, and in other examples, the motor 502 can be another type of motor. The motor 502 is communicatively coupled to the controller 190, and the controller 190 is configured to control operation of the motor 502.

The motor 502 is disposed on and supported by the frame 506 in the illustrated example. In other examples, the motor 502 and the frame 506 may be separated and fixed relative to each other. For example, the frame 506 may be attached to or integral with the substrate support 106, and the motor 502 may be disposed fixedly in the pedestal 114.

The frame 506 has the vertical brackets 508 disposed at respective locations along an edge of the frame 506. The vertical brackets 508 project vertically (e.g., in a z-direction) from the frame 506. A respective lateral translation guide track 510 is disposed on each vertical bracket 508 (e.g., at a top of the vertical bracket 508 proximate the support surface 116). A respective segment support 512 is mechanically coupled or attached to each lateral translation guide track 510. The lateral translation guide tracks 510 are arranged and mechanically coupled to the respective segment support 512 to permit lateral, radial translation of the respective segment support 512 along the respective lateral translation guide track 510.

Each linkage 514 is mechanically coupled between a respective segment support 512 and the drive shaft 504. The linkages 514 are mechanically coupled to the segment supports 512 and drive shaft 504 via pins 516 or other hinged couplings. As illustrated, first ends of the linkages 514 are mechanically coupled via pins 516 to respective segment supports 512, and second ends (e.g., opposite the respective first ends) are mechanically coupled via pins 516 to the drive shaft 504. The linkages 514 (and pins 516) are configured to change vertical translation (e.g., along a z-direction) of the drive shaft 504 to a lateral, radial translation (e.g., in an x-y plane in a radial direction from a center of the segmented focus ring) of the focus ring segments 140.

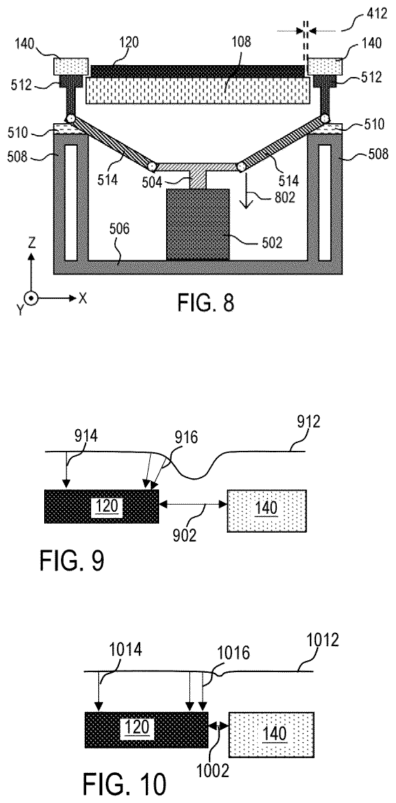

FIGS. 7 and 8 illustrate lateral, radial translation of the focus ring segments 140 by the focus ring radial translation assembly of FIGS. 5 and 6. Referring to FIG. 7, the drive shaft 504 is in a projected position from the motor 502, which causes the segment supports 512 (via linkages 514) to be at respective distal lateral, radial positions. The segment supports 512 being at respective distal lateral, radial positions causes respective greatest lateral, radial gaps 422 between the focus ring segments 140 and an edge of the semiconductor substrate 120.

Referring to FIG. 8, the drive shaft 504 moves 802 vertically by operation of the motor 502 to a retracted position, which causes the segment supports 512 (via linkages 514) to be at respective proximal lateral, radial positions. The segment supports 512 being at respective proximal lateral, radial positions causes respective smallest lateral, radial gaps 412 between the focus ring segments 140 and the edge of the semiconductor substrate 120.

Generally, as the motor 502 operates to move the drive shaft 504 to the projected position of FIG. 7, the linkages 514 change the vertical movement (e.g., upward movement) of the drive shaft 504 to outward lateral, radial translations of the segment supports 512, which translate along the respective lateral translation guide tracks 510. Hence, the motor 502 moving the drive shaft 504 toward a projected position operates to increase the gaps between the focus ring segments 140 and the semiconductor substrate 120. As the motor 502 operates to move the drive shaft 504 to the retracted position of FIG. 8, the linkages 514 change the vertical movement (e.g., downward movement) of the drive shaft 504 to inward lateral, radial translations of the segment supports 512, which translate along the respective lateral translation guide tracks 510. Hence, the motor 502 moving the drive shaft 504 toward a retracted position operates to decrease the gaps between the focus ring segments 140 and the semiconductor substrate 120.

FIGS. 9 and 10 illustrate how gaps between the focus ring segments 140 and an edge of a semiconductor substrate 120 can contribute to plasma control according to some embodiments of the present disclosure. FIGS. 9 and 10 are cross-sectional views of the semiconductor substrate 120 and a focus ring segment 140 (as disposed in the processing tool 100 in FIG. 1). In FIG. 9, a lateral, radial gap 902 is between the semiconductor substrate 120 and a focus ring segment 140, and in FIG. 10, a lateral, radial gap 1002 is between the semiconductor substrate 120 and a focus ring segment 140. The lateral, radial gap 902 in FIG. 9 is greater than the lateral, radial gap 1002 in FIG. 10. In FIG. 9, plasma sheath 912 dips into the radial gap 902, and in FIG. 10, plasma sheath 1012 dips into the radial gap 1002. The plasma sheath 912 dips into the radial gap 902 in FIG. 9 more than the plasma sheath 1012 dips into the radial gap 1002 in FIG. 10. In FIGS. 9 and 10, the plasma sheath 912, 1012 is generally flat at a center of the semiconductor substrate 120, and hence, ion bombardment 914, 1014 from the plasma on the center of the semiconductor substrate 120 can be generally normal to the top surface of the semiconductor substrate 120. In FIG. 9, at the edge of the semiconductor substrate 120, the plasma sheath 912 is curved as the plasma sheath 912 dips into the radial gap 902, and hence, ion bombardment 916 from the plasma at the edge of the semiconductor substrate 120 can be generally off-normal (e.g., some angle from normal) to the top surface of the semiconductor substrate 120. Referring to FIG. 10, at the edge of the semiconductor substrate 120, the plasma sheath 1012 is curved less severely as the plasma sheath 1012 lightly dips into the radial gap 1002, and hence, ion bombardment 1016 from the plasma at the edge of the semiconductor substrate 120 can be generally closer to normal to the top surface of the semiconductor substrate 120. Hence, ion bombardment 1014 at the center of the semiconductor substrate 120 and ion bombardment 1016 at the edge of the semiconductor substrate 120 can both be generally normal to the top surface of the semiconductor substrate 120. Accordingly, adjusting gaps between an edge of the semiconductor substrate 120 and the focus ring segments 140 can control curve of the plasma sheath and a resulting angle of ion bombardment on the semiconductor substrate 120.

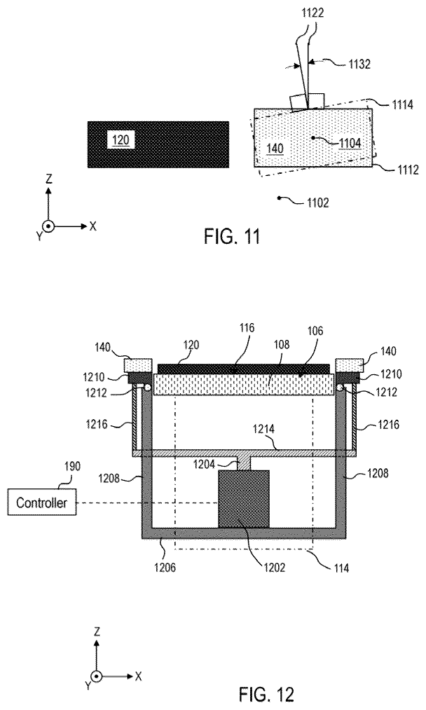

In some embodiments of the present disclosure, the focus ring movement assembly is a focus ring tilt assembly that is configured to tilt the focus ring segments 140 (e.g., in respective angles relative to an axis normal to the support surface 116). FIG. 11 is a cross-sectional view of a focus ring segment 140 of a segmented focus ring illustrating tilting of the focus ring segment 140 according to some embodiments of the present disclosure. Each focus ring segment 140 may be tilted around along a respective lateral axis perpendicular to a respective lateral, radial direction 402 from a center of the segmented focus ring (e.g., in an x-y plane parallel to the support surface 116 and/or a top surface of the semiconductor substrate 120). The lateral axis around which the focus ring segment may be tilted may be exterior to the focus ring segment 140 (e.g., axis 1102 in a y-direction in FIG. 11) or may intersect the focus ring segment 140 (e.g., axis 1104 in a y-direction in FIG. 11). FIG. 11 shows a first tilt position 1112 and a second tilt position 1114 of the focus ring segment 140. An axis 1122 normal to a top surface of the focus ring segment 140 is shown relative to the first tilt position 1112 and the second tilt position 1114. A tilt angle 1132 is between the axis 1122 at the first tilt position 1112 and the second tilt position 1114. The range of the tilt angle 1132 can be any range. The tilt angle 1132 can be positive or negative relative to when the focus ring segment 140 is in an un-tilted position (e.g., a top surface of the focus ring segment 140 is parallel to the support surface 116).

FIG. 12 is a simplified cross-sectional view of the focus ring tilt assembly according to some embodiments of the present disclosure. The focus ring tilt assembly in this example is configured to support and move six focus ring segments 140. In other examples, the focus ring tilt assembly may be configured to support any number of focus ring segments 140. A semiconductor substrate 120, focus ring segments 140, ESC 108, pedestal 114, and controller 190 are shown for context in FIG. 12.

The focus ring tilt assembly includes a motor 1202 having a drive shaft 1204, a fixed frame 1206 having vertical brackets 1208, segment supports 1210, hinges 1212, a moveable frame 1214, and lift pins 1216. The motor 1202 is configured to vertically project and retract the drive shaft 1204 (e.g., along a z-direction). In some embodiments of the present disclosure, the motor 1202 is a stepper motor (e.g., a helical stepper motor), a pneumatic motor, or a linear actuator/drive motor, and in other examples, the motor 1202 can be another type of motor. The motor 1202 is communicatively coupled to the controller 190, and the controller 190 is configured to control operation of the motor 1202.

The motor 1202 is disposed on and supported by the fixed frame 1206 in the illustrated example of FIG. 12. In other examples, the motor 1202 and the fixed frame 1206 may be separated and fixed relative to each other. For example, the fixed frame 1206 may be attached to or integral with the substrate support 106, and the motor 1202 may be disposed fixedly in the pedestal 114.

The fixed frame 1206 has the vertical brackets 1208 disposed at respective locations along an edge of the fixed frame 1206. The vertical brackets 1208 project vertically (e.g., in a z-direction) from the frame 1206. A respective segment support 1210 is mechanically coupled to a respective one or more vertical brackets 1208. The segment support 1210 may be mechanically coupled to the one or more vertical brackets 1208 by any coupling that permits the segment support 1210 to be tilted, such as by a hinge 1212.

A moveable frame 1214 is mechanically attached to the drive shaft 1204. The moveable frame 1214 extends laterally beyond (e.g., through) the vertical brackets 1208. Lift pins 1216 are mechanically attached to the moveable frame 1214 and project vertically (e.g., in a z-direction) from the moveable frame 1214. One or more of the lift pins 1216 contacts a lower surface of a respective segment support 1210. A location where a lift pin 1216 contacts the lower surface of the segment support 1210 is laterally, radially more distal from a center of the segmented focus ring than where the hinge 1212 is located, in this example. By having the hinge 1212 located more proximate to the support surface 116, and hence, the semiconductor substrate 120, a tilting action of the segment supports 1210 can result in the focus ring segments 140 remaining nearer to the support surface 116, and hence, the semiconductor substrate 120.

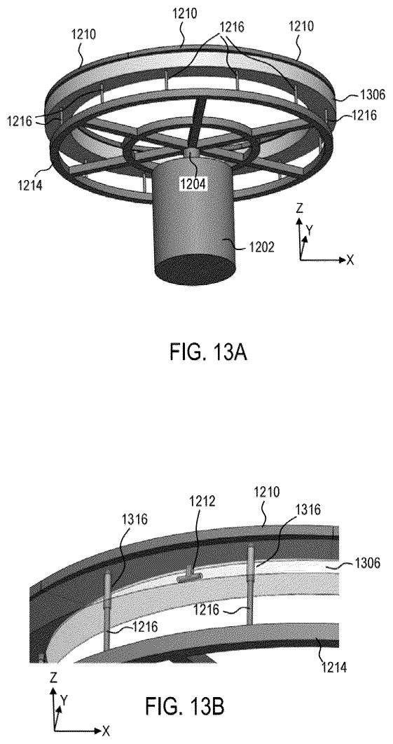

FIG. 13A is a perspective view of a focus ring tilt assembly, according to some embodiments of the present disclosure, and FIG. 13B is a perspective view of a portion of the focus ring tilt assembly of FIG. 13A. The focus ring tilt assembly of FIGS. 13A and 13B is generally the focus ring tilt assembly of FIG. 12; hence, description of like components is omitted here. FIGS. 13A and 13B illustrate a fixed frame 1306 that is attached to or integral with the substrate support 106. The lift pins 1216 extend vertically through the fixed frame 1306 (e.g., through respective openings 1316). In FIGS. 13A and 13B, two lift pins 1216 contact a lower surface of a respective segment support 1210.

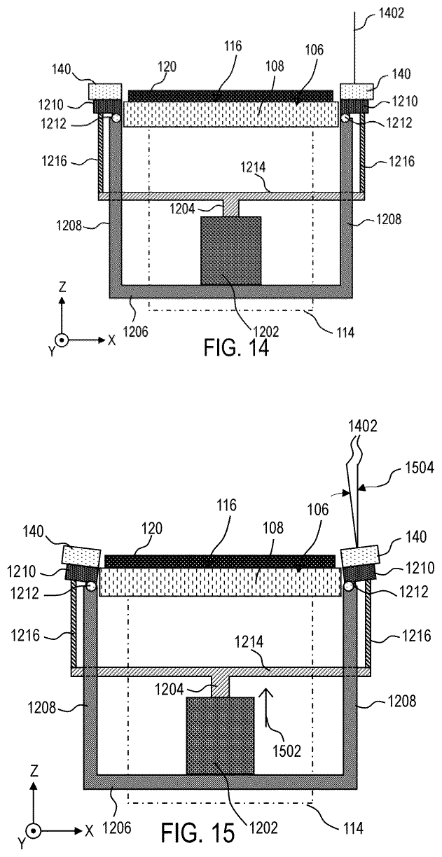

FIGS. 14 and 15 illustrate tilting of the focus ring segments 140 by the focus ring tilt assembly of FIG. 12. Referring to FIG. 14, the drive shaft 1204 is in a first position from the motor 1202, which causes the segment supports 1210 to have respective top surfaces parallel with the support surface 116. An axis 1402 normal to a top surface of a focus ring segment 140 is parallel to an axis normal to the support surface 116 (e.g., in a z-direction).

Referring to FIG. 15, the drive shaft 1204 moves 1502 vertically by operation of the motor 1202 to a second (e.g., projected) position, which causes the lift pins 1216 to move vertically. The vertical movement of the lift pins 1216 pushes the radially distal portions of the segment supports 1210 vertically. With the hinges 1212 mechanically coupling the segment supports 1210 and the lift pins 1216 pushing the segment supports 1210, the segment supports 1210 are caused to tilt (e.g., rotate some amount around the respective hinge 1212). The tilting of the segment supports 1210 is by an angle 1504 of the axis 1402 in the position of FIG. 15 relative to the axis 1402 in the position of FIG. 14.

Generally, as the motor 1202 operates to move the drive shaft 1204 to a more retracted position, the lift pins 1216 are lowered causing the segment supports 1210, and focus ring segments 140 thereon, to rotate around respective hinges in a rotational direction away from the support surface 116 and/or semiconductor substrate 120. As the motor 1202 operates to move the drive shaft 1204 to a more projected position, the lift pins 1216 are raised causing the segment supports 1210, and focus ring segments 140 thereon, to rotate around respective hinges in a rotational direction toward the support surface 116 and/or semiconductor substrate 120.

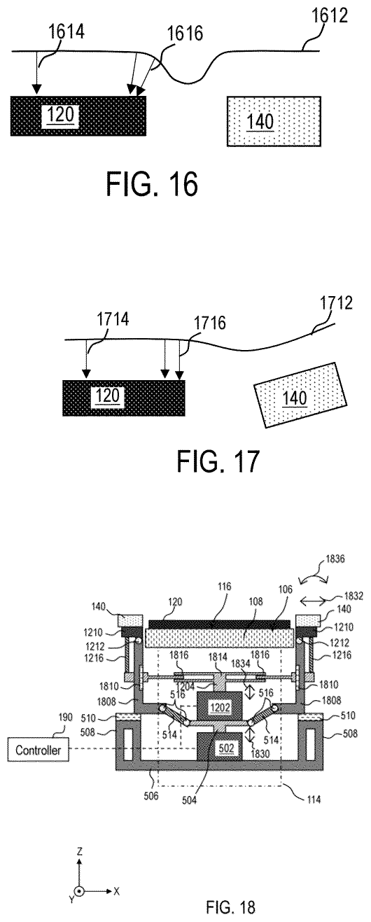

FIGS. 16 and 17 illustrate how tilt of the focus ring segments 140 can contribute to plasma control according to some embodiments of the present disclosure. FIGS. 16 and 17 are cross-sectional views of the semiconductor substrate 120 and a focus ring segment 140 (as disposed in the processing tool 100 in FIG. 1). In FIG. 16, the focus ring segment 140 has a top surface parallel to a top surface of the semiconductor substrate, and in FIG. 17, the focus ring segment 140 is tilted toward (e.g., rotated toward) the semiconductor substrate 120 some amount. In FIG. 16, plasma sheath 1612 dips into a gap between the edge of the semiconductor substrate 120 and the focus ring segment 140, and in FIG. 17, plasma sheath 1712 dips less significantly into the gap and contours the tilting focus ring segment 140. In FIGS. 16 and 17, the plasma sheath 1612, 1712 is generally flat at a center of the semiconductor substrate 120, and hence, ion bombardment 1614, 1714 from the plasma on the center of the semiconductor substrate 120 can be generally normal to the top surface of the semiconductor substrate 120. In FIG. 16, at the edge of the semiconductor substrate 120, the plasma sheath 1612 is curved as the plasma sheath 1612 dips into the gap, and hence, ion bombardment 1616 from the plasma at the edge of the semiconductor substrate 120 can be generally off-normal (e.g., some angle from normal) to the top surface of the semiconductor substrate 120. Referring to FIG. 17, at the edge of the semiconductor substrate 120, the plasma sheath 1712 is curved less severely as the plasma sheath 1712 lightly dips into the gap, and hence, ion bombardment 1716 from the plasma at the edge of the semiconductor substrate 120 can be generally closer to normal to the top surface of the semiconductor substrate 120. Hence, ion bombardment 1714 at the center of the semiconductor substrate 120 and ion bombardment 1716 at the edge of the semiconductor substrate 120 can both be generally normal to the top surface of the semiconductor substrate 120. Accordingly, adjusting a tilt of the focus ring segments 140 can control curve of the plasma sheath and a resulting angle of ion bombardment on the semiconductor substrate 120.

In some embodiments of the present disclosure, the focus ring movement assembly includes a focus ring radial translation sub-assembly and a focus ring tilt sub-assembly. FIG. 18 illustrates an example of such a focus ring movement assembly. Generally, as apparent from FIG. 18, the focus ring radial translation sub-assembly includes like components as the focus ring radial translation assembly of FIG. 5, and the focus ring tilt sub-assembly includes like components as the focus ring tilt assembly of FIG. 12. Some components in the focus ring movement assembly of FIG. 18 may be considered to be components of both the focus ring radial translation sub-assembly and the focus ring tilt sub-assembly.

The focus ring movement assembly includes motors 502, 1202 having respective drive shafts 504, 1204, a frame 506 having vertical brackets 508, lateral translation guide tracks 510, linkages 514, moveable brackets 1808, vertical translation guide tracks 1810, segment supports 1210, a frame 1814 having telescopic arms 1816, and lift pins 1216. The motor 502, drive shaft 504, frame 506, vertical brackets 508, and lateral translation guide tracks 510 are generally configured as described with respect to FIG. 5. A respective moveable bracket 1808 is mechanically coupled or attached to each lateral translation guide track 510. The lateral translation guide tracks 510 are arranged and mechanically coupled to the respective moveable bracket 1808 to permit lateral, radial translation of the respective moveable bracket 1808 along the respective lateral translation guide track 510. A respective segment support 1210 is mechanically coupled to a respective moveable bracket 1808. The segment support 1210 may be mechanically coupled to the moveable bracket 1808 by any coupling that permits the segment support 1210 to be tilted, such as by a hinge 1212.

Each linkage 514 is mechanically coupled between a respective moveable bracket 1808 and the drive shaft 504. The linkages 514 are mechanically coupled to the moveable bracket 1808 and drive shaft 504 via pins 516 or other hinged couplings. The linkages 514 (and pins 516) are configured to change vertical translation (e.g., along a z-direction) of the drive shaft 504 to a lateral, radial translation (e.g., in an x-y plane in a radial direction from a center of the segmented focus ring) of the focus ring segments 140.

The motor 1202 is disposed on and supported by the drive shaft 504. The frame 1814 is mechanically attached to the drive shaft 1204 of the motor 1202. The telescopic arms 1816 are mechanically attached to the frame 1814. Radially outer portions (e.g., tubes) of the telescopic arms 1816 are configured to be radially translated relative to radially inner portions of the telescopic arms 1816 that are mechanically attached to the frame 1814. The radially outer portions of the telescopic arms 1816 are mechanically coupled to the vertical translation guide tracks 1810. Lift pins 1216 are mechanically attached to respective radially outer portions of the telescopic arms 1816 and project vertically (e.g., in a z-direction) from the telescopic arms 1816. The telescopic arms 1816 and vertical translation guide tracks 1810 are configured to maintain the positioning of the lift pins 1216 relative to the respective segment supports 1210 as the moveable brackets 1808 move radially, laterally along the lateral translation guide tracks 510. The vertical translation guide tracks 1810 generally do not permit lateral movement of the radially outer portions of the telescopic arms 1816 relative to the respective moveable brackets 1808. Hence, as a moveable bracket 1808 moves laterally, radially, the respective telescopic arm 1816 retract or project corresponding to the movement of the moveable bracket 1808.

Generally, as the motor 502 operates to vertically move 1830 the drive shaft 504, the linkages 514 change the vertical movement 1830 of the drive shaft 504 to lateral, radial translations of the moveable brackets 1808 (and hence, the segment supports 1210), which translate along the respective lateral translation guide tracks 510. Hence, the motor 502 vertically moving 1830 the drive shaft 504 operates to laterally, radially translate 1832 the segment supports 1210, thereby adjusting the gaps between the focus ring segments 140 and the semiconductor substrate 120. Generally, as the motor 1202 operates to vertically move 1834 the drive shaft 1204, the telescopic arms 1816 are vertically translated along the vertical translation guide tracks 1810, which causes the lift pins 1216 to be vertically moved. Vertical movement of the lift pins 1216 causes the segment supports 1210, and respective focus ring segments 140 thereon, to tilt 1836 around respective hinges 1212.

Since, in the illustrated example, the motor 1202 is disposed on and supported by the drive shaft 504, when the motor 502 is operated to move the drive shaft 504, the motor 1202 may, in some instances, operate reciprocally or in conjunction with the operation of the motor 502. For example, if the motor 502 is to operate to laterally move the segment supports 1210, the movement of the drive shaft 504 would vertically move the motor 1202 and drive shaft 1204, which would cause vertical movement of the lift pins 1216. If in such a situation a tilt of the segment supports 1210 is to be maintained with radial, lateral movement, the drive shaft 1204 would be moved in an opposite direction in an equal distance of movement from the drive shaft 504. The controller 190 communicatively coupled to the motors 502, 1202 may control and coordinate such movement of the drive shafts 504, 1204 in addition to general control of the motors 502, 1202.

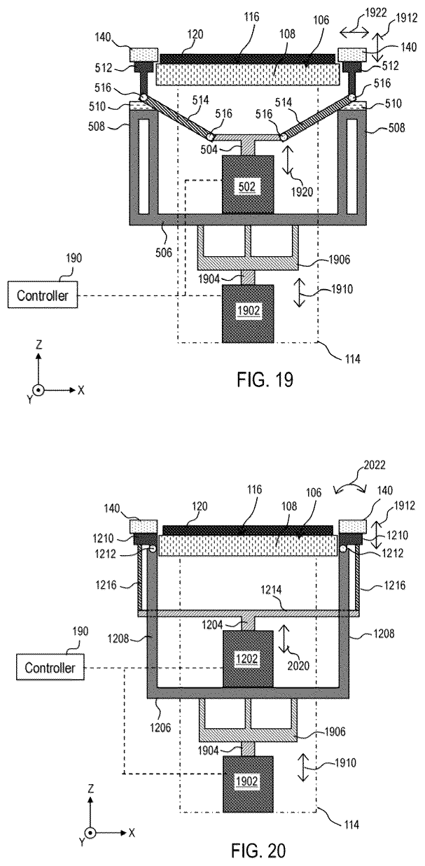

In some embodiments of the present disclosure, the focus ring movement assembly includes a focus ring vertical translation sub-assembly in addition to a focus ring radial translation sub-assembly and/or a focus ring tilt sub-assembly. FIGS. 19, 20, and 21 are simplified cross-sectional views of respective focus ring movement assemblies that include a focus ring vertical translation sub-assembly according to some embodiments of the present disclosure. The focus ring vertical translation sub-assembly includes a motor 1902 having a drive shaft 1904 and includes a frame 1906. The frame 1906 is mechanically attached to the drive shaft 1904. The motor 1902 is communicatively coupled to the controller 190, and the controller 190 is configured to control operation of the motor 1902.

Referring to FIG. 19 the focus ring movement assembly includes the focus ring vertical translation sub-assembly in addition to a focus ring radial translation sub-assembly. The focus ring radial translation sub-assembly is the focus ring radial translation assembly of FIG. 5. The frame 506 is mechanically attached to and supported by the frame 1906. As described with respect to FIG. 5, vertical movement 1920 of the drive shaft 504 by the motor 502 causes lateral, radial translation 1922 of the segment supports 512. Vertical movement 1910 of the drive shaft 1904 causes vertical movement of the focus ring radial translation sub-assembly, and thereby, vertical movement 1912 of the segment supports 512.

Referring to FIG. 20 the focus ring movement assembly includes the focus ring vertical translation sub-assembly in addition to a focus ring tilt sub-assembly. The focus ring tilt sub-assembly is the focus ring tilt assembly of FIG. 12. The frame 1206 is mechanically attached to and supported by the frame 1906. As described with respect to FIG. 12, vertical movement 2020 of the drive shaft 1204 by the motor 1202 causes tilting 2022 of the segment supports 1210. Vertical movement 1910 of the drive shaft 1904 causes vertical movement of the focus ring tilt sub-assembly, and thereby, vertical movement 1912 of the segment supports 1210.

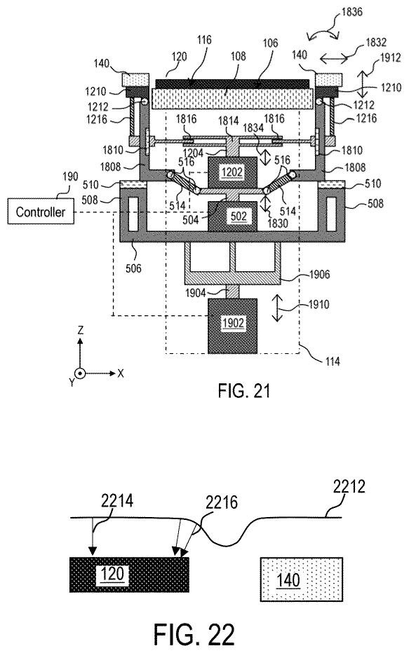

Referring to FIG. 21 the focus ring movement assembly includes the focus ring vertical translation sub-assembly in addition to a focus ring radial translation sub-assembly and a focus ring tilt sub-assembly. The focus ring radial translation sub-assembly and focus ring tilt sub-assembly are as shown in and described with respect to FIG. 18. The frame 506 is mechanically attached to and supported by the frame 1906. As described with respect to FIG. 18, vertical movement 1830 of the drive shaft 504 by the motor 502 causes lateral, radial translation 1832 of the segment supports 1210, and vertical movement 1834 of the drive shaft 1204 by the motor 1202 causes tilting 1836 of the segment supports 1210. Vertical movement 1910 of the drive shaft 1904 causes vertical movement of the focus ring radial translation sub-assembly and focus ring tilt sub-assembly, and thereby, vertical movement 1912 of the segment supports 1210.

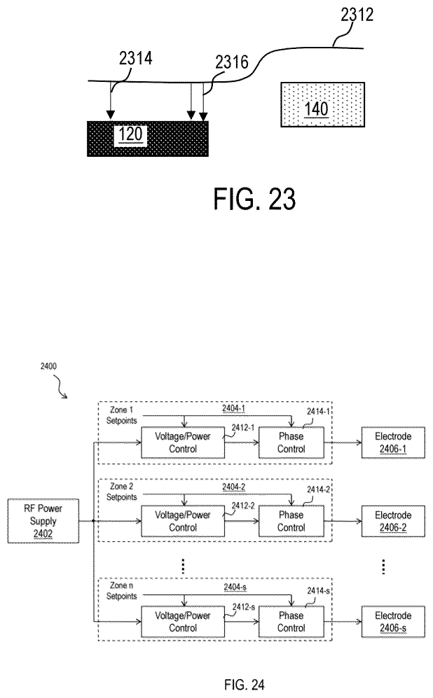

FIGS. 22 and 23 illustrate how vertical translation of the focus ring segments 140 can contribute to plasma control according to some embodiments of the present disclosure. FIGS. 22 and 23 are cross-sectional views of the semiconductor substrate 120 and a focus ring segment 140 (as disposed in the processing tool 100 in FIG. 1). In FIG. 22, the focus ring segment 140 is at a first vertical position, and in FIG. 23, the focus ring segment 140 is at a second vertical position higher than the first vertical position. In FIG. 22, plasma sheath 2212 dips into a gap between the edge of the semiconductor substrate 120 and the focus ring segment 140, and in FIG. 23, plasma sheath 2312 contours up to the focus ring segment 140. In FIGS. 22 and 23, the plasma sheath 2212, 2312 is generally flat at a center of the semiconductor substrate 120, and hence, ion bombardment 2214, 2314 from the plasma on the center of the semiconductor substrate 120 can be generally normal to the top surface of the semiconductor substrate 120. In FIG. 22, at the edge of the semiconductor substrate 120, the plasma sheath 2212 is curved as the plasma sheath 2212 dips into the gap, and hence, ion bombardment 2216 from the plasma at the edge of the semiconductor substrate 120 can be generally off-normal (e.g., some angle from normal) to the top surface of the semiconductor substrate 120. Referring to FIG. 23, at the edge of the semiconductor substrate 120, the plasma sheath 2312 is curved less severely as the plasma sheath 2312 contours up to the focus ring segment 140, and hence, ion bombardment 2316 from the plasma at the edge of the semiconductor substrate 120 can be generally closer to normal to the top surface of the semiconductor substrate 120. Hence, ion bombardment 2314 at the center of the semiconductor substrate 120 and ion bombardment 2316 at the edge of the semiconductor substrate 120 can both be generally normal to the top surface of the semiconductor substrate 120. Accordingly, adjusting a vertical position of the focus ring segments 140 can control curve of the plasma sheath and a resulting angle of ion bombardment on the semiconductor substrate 120.

FIG. 24 is a schematic of an RF power system 2400 of the processing tool 100 according to some embodiments of the present disclosure. The RF power system 2400 includes an RF power supply 2402, s number of signal control circuits 2404, and s number of electrodes 2406. The RF power supply 2402 can be the RF power supply 164, 168, 180 (each of which may include an RF power generator and an RF matching network); the signal control circuits 2404 can be the signal control circuits 166, 172, 182; and the electrodes 2406 can be the RF electrodes 132, the bias electrodes 136, and/or the electrodes 250 and/or resistive heating elements 350 of focus ring segments 140.

Each signal control circuit 2404 includes a respective voltage/power control circuit 2412 and a respective phase control circuit 2414. For example, the signal control circuit 2404-1 includes a voltage/power control circuit 2412-1 and a phase control circuit 2414-1, and the signal control circuit 2404-s includes a voltage/power control circuit 2412- s and a phase control circuit 2414-s. Each voltage/power control circuit 2412 has an input node that is the input node of the respective signal control circuit 2404 and is electrically coupled to the output node of the RF power supply 2402. Each voltage/power control circuit 2412 has an output node electrically coupled to an input node of a respective phase control circuit 2414. Each phase control circuit 2414 has an output node that is the output node of the respective signal control circuit 2404 that is electrically coupled to a respective electrode 2406. The voltage/power control circuit 2412 and the phase control circuit 2414 of a respective signal control circuit 2404 are communicatively coupled to, e.g., the controller 190 to receive one or more setpoints for the respective signal control circuit 2404. The setpoint(s) is a digital number or code that selectively configures the gain of the voltage/power control circuit 2412 and the phase offset of the phase control circuit 2414.

In some embodiments of the present disclosure, a voltage/power control circuit 2412 can include an amplifier and a selectively configurable impedance network configured to receive an RF voltage and output a gain-adjusted RF voltage relative to the received RF voltage. The selectively configurable impedance network can include a number of parallel connected switched resistors, for example. For example, a switched resistor can include a resistor electrically connected in series with a channel of a transistor. A signal, which can be a bit of the setpoint or a bit resulting from decoding the setpoint, for example, can be applied to the gate of the transistor to selectively cause the channel of the transistor to be in a conducting state or non-conducting state. By selectively electrically connecting and/or disconnecting resistors in parallel, the gain of the voltage/power control circuit 2412 can be selectively configured. A person having ordinary skill in the art will readily understand a configuration for a voltage/power control circuit 2412 and how such voltage/power control circuit 2412 can be selectively configurable to implement different gains, which may be by using any combination of impedance elements, such as resistors, capacitors, and/or inductors.

Similarly, in some embodiments of the present disclosure, a phase control circuit 2414 can include an amplifier and a selectively configurable impedance network configured to receive an RF voltage and output a phase-offset-adjusted RF voltage relative to the received RF voltage. The selectively configurable impedance network can include a number of parallel connected switched impedance elements, including, for example, resistors, capacitors, and/or inductors. A signal, which can be a bit of the setpoint or a bit resulting from decoding the setpoint, for example, can be applied to the gate of the transistor to selectively cause the channel of the transistor to be in a conducting state or non-conducting state. By selectively electrically connecting and/or disconnecting impedance elements in parallel, the phase offset of the phase control circuit 2414 can be selectively configured. A person having ordinary skill in the art will readily understand a configuration for a phase control circuit 2414 and how such phase control circuit 2414 can be selectively configurable to implement different phase offsets.

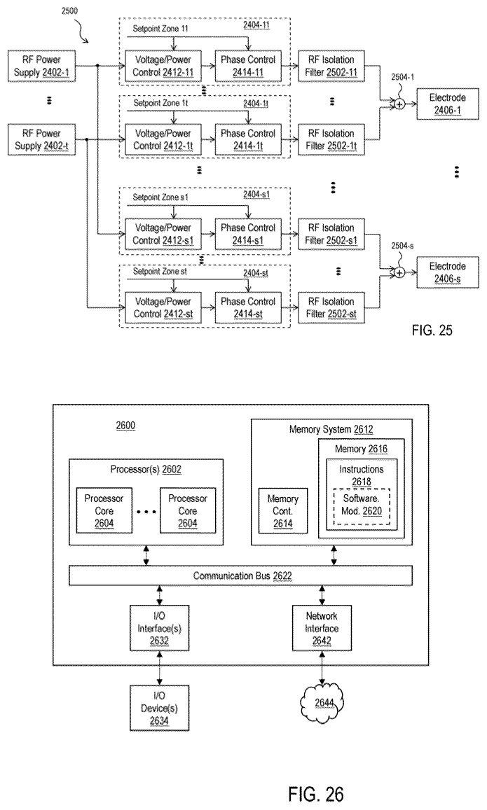

FIG. 25 is a schematic of an RF power system 2500 that may be implemented with the processing tool 100 according to some embodiments of the present disclosure. The RF power system 2500 of FIG. 25 is a modification of the RF power system 2400 of FIG. 24. The RF power system 2400 is a multi-frequency RF power system. The RF power system 2400 includes t number of RF power supplies 2402. Each RF power supply 2402 is configured to generate an RF voltage at a target frequency, and the target frequencies of the RF power supplies 2402 can be different. For example, a target frequency of the RF power supply 2402-1 may be 13.56 MHz, and a target frequency of the RF power supply 2402- t may be 60 MHz.

The RF power system 2500 includes s number of signal control circuits 2404 for each RF power supply 2402. In total, the RF power system 2500 includes (s x t) number of signal control circuits 2404. In the illustration, each signal control circuit 2404 has a “-ij” designation appended thereto, where i indicates with which electrode 2406 the given signal control circuit 2404 is associated, and j indicates with which RF power supply 2402 the given signal control circuit 2404 is associated. Each signal control circuit 2404 includes a voltage/power control circuit 2412 and a phase control circuit 2414 and is configured as described above with respect to FIG. 24.

For each RF power supply 2402, an output node of the respective RF power supply 2402 is electrically coupled to input nodes of s number of signal control circuits 2404 associated with that RF power supply 2402. Each signal control circuit 2404 has an output node electrically coupled to an input node of a respective RF isolation filter 2502 (which have a designation appended like with the signal control circuits 2404). Each RF isolation filter 2502 is configured to pass an RF voltage having the target frequency of the RF voltage generated by the associated RF power supply 2402. Each RF isolation filter 2502 may remove or diminish any signal some amount of frequency from the target frequency. For example, an RF isolation filter 2502 can be a bandpass filter centered on the frequency of the RF voltage generated by the associated RF power supply 2402.

The RF power system 2500 includes s number of analog summer/adder circuits 2504. Each analog summer/adder circuit 2504 has t number of input nodes and is associated with a respective electrode 2406. Output nodes of respective RF isolation filters 2502 associated with a given electrode 2406 are electrically coupled to respective input nodes of the analog summer/adder circuit 2504 associated with that given electrode 2406. Each analog summer/adder circuit 2504 is configured to sum the t number of RF voltages received from the respective RF isolation filters 2502 to generate an RF voltage. Each analog summer/adder circuit 2504 has an output node electrically coupled to the electrode 2406 with which the analog summer/adder circuit 2504 is associated. The RF voltage generated by the analog summer/adder circuit 2504 is output on the output node to the electrode 2406. By having multiple RF power supplies 2402 that generate RF voltages with different frequencies, an RF voltage can include multiple RF components that are applied to an electrode 2406. Other aspects of the RF power system 2500 are apparent to a person having ordinary skill in the art in view of previous description, including description of the RF power system 2400 of FIG. 24.

FIG. 26 illustrates a processor-based system 2600 according to some embodiments of the present disclosure. The processor-based system 2600 can be or include a computer, a server, a PLC, the like, or a combination thereof. The processor-based system 2600 may be implemented as the controller 190 or as any other processor-based system to implement any operations described herein. The processor-based system 2600 includes one or more processors 2602, a memory system 2612, a communication bus 2622, one or more input/output (I/O) interfaces 2632, and a network interface 2642.

Each processor 2602 can include one or more processor cores 2604. Each processor 2602 and/or processor core 2604 may be, for example, a hardened processor, such as a central processing unit (CPU), a reduced instruction set computing (RISC) processor, a complex instruction set computing (CISC) processor, a graphics processing unit (GPU), a digital signal processor (DSP), an application specific integrated circuit (ASIC), the like, or a combination thereof, or a soft processor implemented on programmable logic, such as a FPGA.

The memory system 2612 includes one or more memory controllers 2614 and memory 2616. The memory controllers 2614 are configured to control reading and/or writing access to a particular memory 2616 or subset of memory 2616. The memory 2616 may include main memory, disk storage, or any suitable combination thereof. The memory 2616 may include any type of volatile or nonvolatile memory, such as dynamic random access memory (DRAM), static random access memory (SRAM), erasable programmable read-only memory (EPROM), electrically erasable programmable read-only memory (EEPROM), Flash memory, solid-state storage, etc. The memory 2616 is a non-transitory machine-readable storage medium. Instructions 2618 are stored in the memory 2616. The instructions 2618 may be machine-executable code (e.g., machine code) and may comprise firmware, software, a program, an application, or other machine-executable code. The instructions 2618 can, for example, embody a software module 2620, which when executed by the one or more processors 2602, performs various functionality and operations described herein.

The one or more I/O interfaces 2632 are configured to be electrically and/or communicatively coupled to one or more I/O devices 2634. The I/O devices 2634 include the signal control circuits 166, 172, 182 and the motors 502, 1202, 1902. The signal control circuits 166, 172, 182 and motors 502, 1202, 1902 can receive respective setpoints via the I/O interface 2632. Other example I/O devices 2634 include a keyboard, a mouse, a display device, a printer, etc. The one or more I/O interfaces 2632 can include connectors or coupling circuitry, such as an industrial application connection, a universal serial bus (USB) connection, a high-definition multimedia interface (HDMI) connection, Bluetooth® circuitry, or the like.

The network interface 2642 is configured to be communicatively coupled to a network 2644. The network interface 2642 can include circuitry for wired communication, such as an Ethernet connection, and/or can include circuitry for wireless communication, such as a circuitry for Wi-Fi® communications. For example, one or more computers and/or servers communicatively coupled to the network 2644 may communicate a recipe, process conditions, or the like to the processor-based system 2600 via the network 2644 and the network interface 2642.

The communication bus 2622 is communicatively connected to the one or more processors 2602, the memory system 2612, the one or more I/O interfaces 2632, and the network interface 2642. The various components can communicate between each other via the communication bus 2622. The communication bus 2622 can control the flow of communications, such as by including an arbiter to arbitrate the communications.

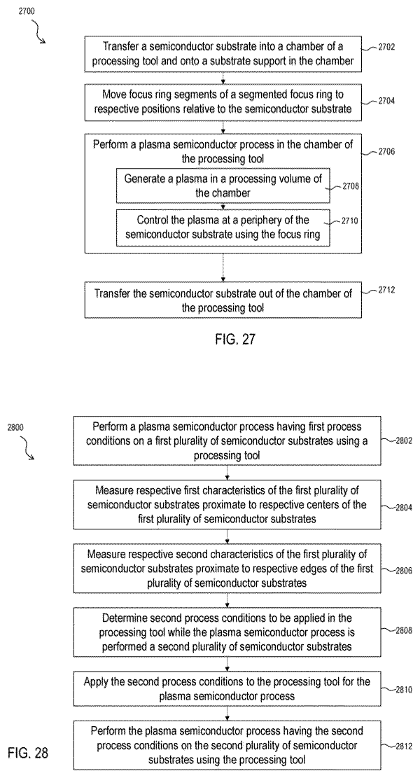

FIG. 27 is a flow chart of a method 2700 of semiconductor processing according to some embodiments of the present disclosure. The method 2700 can be implemented using the processing tool 100 previously described. The operations of the method 2700 can be initiated and/or controlled by the controller 190 (e.g., by execution of instructions 2618 by the one or more processors 2602). At block 2702, a semiconductor substrate 120 is transferred into a chamber 102 of a processing tool 100 and onto a substrate support 106 (e.g., an ESC 108) in the chamber 102. A segmented focus ring (including focus ring segments 140) can be disposed on the focus ring movement assembly as the semiconductor substrate 120 is transferred into the chamber 102. The semiconductor substrate 120 can be secured to the ESC 108 by applying a DC voltage to the chucking electrodes 122 (e.g., to chuck the semiconductor substrate 120). The DC voltage can be generated by the DC power supply 160 and applied to the chucking electrodes 122. With the semiconductor substrate 120 transferred into the chamber 102 and disposed on the support surface 116, the segmented focus ring is disposed laterally encircling the semiconductor substrate 120.

At block 2704, the focus ring segments 140 of the segmented focus ring are moved to respective positions relative to the semiconductor substrate 120. The focus ring segments 140 can be moved by being laterally, radially translated to adjust gaps between the semiconductor substrate 120 and the focus ring segments 140. The focus ring segments 140 can be moved by being tilted or rotated to adjust angles of top surfaces of the focus ring segments 140 relative to a top surface of the semiconductor substrate 120. Additionally, the focus ring segments 140 can be moved by being vertically translated. Any combination or permutation of movements may be implemented, as described previously. The focus ring segments 140 can be moved by the focus ring movement assembly, which may be any of the focus ring movement assemblies previously described or by any other assembly. The controller 190 can cause a respective motor 502, 1202, 1902 to cause the focus ring segments 140 to be moved, as previously described.

At block 2706, plasma semiconductor process is performed in the chamber 102 of the processing tool 100. The plasma semiconductor process can be, for example, an etch process, a deposition process, or any other applicable process. Example plasma semiconductor processes include sputtering, PVD, MDP, PECVD, IBE, and RIE. Block 2706 includes, at block 2708, generating plasma in the processing volume 154 of the chamber 102. The semiconductor substrate 120 can be exposed to the plasma in the processing volume 154. The plasma can be generated by flowing a gas into the chamber 102 (e.g., from the gas supply system 148 and through the gas inlet 146, gas distribution plate 142, and gas showerhead 144) and applying RF voltages to respective RF electrodes 132. The plasma can be generated as a result of the RF voltages on the RF electrodes 132 and the gas showerhead 144 being grounded.

Block 2706 further includes, at block 2710, controlling the plasma at a periphery of the semiconductor substrate 120. Although described separately for ease, blocks 2708, 2710 can be implemented by a same operation(s). The plasma can be controlled at the periphery of the semiconductor substrate 120 by the RF voltages applied to the RF electrodes 132. The plasma can be controlled at the periphery using the segmented focus ring that includes the focus ring segments 140.

In examples where the focus ring segments 140 include respective electrodes 250, as in FIGS. 2A and 2B, the plasma can be controlled at the periphery by applying respective RF voltages (e.g., RF signals) to the electrodes 250 of the focus ring segments 140 to control an electromagnetic field at the periphery. In examples where the focus ring segments 140 include respective resistive heating elements 350, as in FIGS. 3A and 3B, the plasma can be controlled at the periphery by applying respective RF voltages (e.g., RF signals) to the resistive heating elements 350 of the focus ring segments 140 to flow electrical currents through the resistive heating elements 350 to generate thermal energy. Whether for electrodes 250 or resistive heating elements 350, the voltages can be supplied via the RF power supply 180 and signal control circuits 182, which can be controlled by the controller 190 as described previously, for example.

The plasma can be controlled at the periphery of the semiconductor substrate 120 by respective positions of the focus ring segments 140 relative to the semiconductor substrate 120. As described previously, lateral, radial distances, tilting, and/or vertical positioning of the focus ring segments 140 can control the plasma at the periphery, as previously described. Any combination or permutation of positioning can be implemented. The positioning can be achieved by the movement of the focus ring segments 140 in block 2704.

Additionally, biasing of the bias electrodes 136 can be performed during blocks 2708, 2710. The biasing can include applying RF bias voltages to the bias electrodes 136.

At block 2712, the plasma semiconductor process is concluded, and the semiconductor substrate 120 is transferred out of the chamber 102 of the processing tool 100. At the conclusion of the plasma semiconductor process, the RF voltages can cease being applied to the RF electrodes 132 and bias electrodes 136 (e.g., turn off the RF power supplies 164, 168). Further, the voltages can cease being applied to the electrodes 250 or resistive heating elements 350 of the focus ring segments 140 (e.g., turn off the RF power supply 180). Gas can cease being supplied into the chamber 102 and can be exhausted out of the chamber 102. Then, the focus ring movement assembly may move the focus ring segments 140 to some position to provide clearance for transferring the semiconductor substrate 120. The DC voltage can also be ceased (e.g., by turning off the DC power supply 160) to release the semiconductor substrate 120 from the ESC 108. Thereafter, the semiconductor substrate 120 can be transferred out of the chamber 102.

FIG. 28 is a flow chart of a method 2800 for semiconductor processing according to some embodiments of the present disclosure. At block 2802, plasma semiconductor process, like described with respect to FIG. 27, is performed on a first plurality of semiconductor substrates (e.g., one or more lots of semiconductor substrates) using a processing tool 100. The plasma semiconductor process is performed having first process conditions. The first process conditions can include setpoints of the signal control circuits 166, 172, 182 and the motors 502, 1202, 1902, where applicable. Based on respective setpoints, RF voltages are applied to the RF electrodes 132; RF voltages are applied to the bias electrodes 136; RF voltages (e.g., RF signals) are applied to the electrodes 250 or resistive heating elements 350 of focus ring segments 140; and focus ring segments 140 are positioned according to a lateral, radial position, a tilt position, and/or a vertical position.

At block 2804, respective first characteristics of the first plurality of semiconductor substrates proximate to respective centers of the first plurality of substrates are measured, and at block 2806, respective second characteristics of the first plurality of semiconductor substrates proximate to respective edges of the first plurality of substrates are measured. The first characteristic and the second characteristics can be a same feature or component; the use of “first” and “second” is for ease of reference. The measuring can be performed by metrology tools. In some embodiments of the present disclosure, the first and second characteristics can be or include profile angles of recesses etched by the plasma semiconductor process. In some embodiments of the present disclosure, the first and second characteristics can be or include depths of recesses etched by the plasma semiconductor process. In some embodiments of the present disclosure, the first and second characteristics can be or include thicknesses of films deposited by the plasma semiconductor process. Other characteristics may be measured. Variation between the first characteristics and the second characteristics can indicate non-uniformity of the plasma in the plasma semiconductor process when the first plurality of substrates were processed.

At block 2808, using one or more processor-based systems, second process conditions to be applied in the processing tool while the plasma semiconductor process is performed on a second plurality of semiconductor substrates are determined. The second process conditions are determined based on the first characteristics and the second characteristics measured in blocks 2804, 2806, such as differences between the first characteristics and the second characteristics. The second process conditions are respective same types of process conditions as the first process conditions, although the values or data of the first process conditions and the second process conditions may differ. As an example, a processor-based system operating an advanced process control (APC) algorithm may determine RF voltages (e.g., RF signals, which may include respective amplitudes and phases) to be applied to the RF electrodes 132 and bias electrodes 136, may determine RF voltages (e.g., RF signals, which may include respective amplitudes and phases) to be applied to the electrodes 250 or resistive heating elements 350 of the focus ring segments 140, and may determine positioning of the focus ring segments 140, including lateral, radial positions, tilt positions, and/or vertical positions. The processor-based system operating the APC algorithm may then determine setpoints at which to set, where applicable, the signal control circuits 166, 172, 182 and the motors 502, 1202, 1902.

At block 2810, the second process conditions are applied to the processing tool for the plasma semiconductor process. For example, the processor-based system operating the APC algorithm may communicate the second process conditions (e.g., via network 2644) to the controller 190. The controller 190 can reset the recipe of the plasma semiconductor process to have the second process conditions and can communicate the second process conditions (e.g., the setpoints) to the signal control circuits 166, 172, 182 which causes the signal control circuits 166, 172, 182 to become selectively configured based on the second process conditions, and to the motors 502, 1202, 1902, which causes the motors 502, 1202, 1902 to responsively position the focus ring segments 140.

At block 2812, the plasma semiconductor process is performed on the second plurality of semiconductor substrates using the processing tool 100. The plasma semiconductor process is performed having the second process conditions. Based on the setpoints of the second process conditions, RF voltages are applied, and the motors 502, 1202, 1902 position the focus ring segments 140 during the plasma semiconductor process.

A first embodiment is a processing tool for semiconductor processing. The processing tool includes a chamber, a substrate support, and a focus ring movement assembly. The chamber has an internal volume within the chamber. The substrate support is disposed in the chamber. The substrate support has a support surface configured to support a semiconductor substrate. The focus ring movement assembly is disposed in the chamber. The focus ring movement assembly includes a frame and a plurality of segment supports mechanically coupled to the frame. Each segment support of the plurality of segment supports is configured to support a respective discrete segment of a focus ring. The focus ring includes a plurality of discrete segments. The focus ring movement assembly is configured to support the plurality of discrete segments disposed laterally encircling the support surface. The focus ring movement assembly is configured to translate the plurality of segment supports in respective first directions. Each first direction of the respective first directions is parallel to a respective radial direction that is in a plane of the support surface and from a center of the support surface.

In the processing tool of the first embodiment, the frame may include a plurality of lateral translation guide tracks. Each segment support of the plurality of segment supports may be mechanically coupled to a respective lateral translation guide track of the plurality of lateral translation guide tracks, and the respective segment support may be configured to be laterally translated along the respective lateral translation guide track. The focus ring movement assembly may further include a drive motor that includes a drive shaft, and a plurality of linkages. Each linkage of the plurality of linkages may have a first end mechanically coupled to a respective segment support of the plurality of segment supports and may have a second end mechanically coupled to the drive shaft. The drive motor may be configured to cause movement of the drive shaft and the plurality of linkages, and the movement of the drive shaft and the plurality of linkages may cause the plurality of segment supports to be translated in the respective first directions.

In the processing tool of the first embodiment, the focus ring movement assembly may further be configured to tilt the plurality of segment supports around respective axes, and each axis of the respective axes may be parallel to the support surface.

In the processing tool of the first embodiment, the focus ring movement assembly may further be configured to translate the plurality of segment supports in respective second directions parallel to a direction normal to the support surface.

The processing tool of the first embodiment may further include a plurality of focus ring electrical connectors. Each focus ring electrical connector of the plurality of the focus ring electrical connectors may be configured to electrically connect to and supply a voltage to an electrode of a respective discrete segment of the focus ring.

The processing tool of the first embodiment may further include a plurality of focus ring electrical connectors. Each pair of focus ring electrical connectors of the plurality of the focus ring electrical connectors may be configured to electrically connect to and supply a current to a resistive thermal element of a respective discrete segment of the focus ring.

The processing tool of the first embodiment may further include a power supply and a plurality of control circuits. The power supply may be configured to output a voltage on an output node of the power supply. Each control circuit of the plurality of control circuits may have an input node electrically coupled to the output node of the power supply and may have an output node configured to be electrically coupled to a respective discrete segment of the focus ring. Each control circuit of the plurality of control circuits may be controllable to adjust an amplitude, a phase, or a combination thereof of the voltage and output a corresponding adjusted voltage on the output node of the respective control circuit. Additionally, the processing tool may further include a controller. The controller may include one or more processors and non-transitory memory. The non-transitory memory may include stored instructions, which when executed by the one or more processors, may cause the one or more processors to control the plurality of control circuits to adjust the respective amplitude, the respective phase, or combination thereof.

A second embodiment is a processing tool for semiconductor processing. The processing tool includes a chamber, a substrate support, and a focus ring movement assembly. The chamber has an internal volume within the chamber. The substrate support is disposed in the internal volume of the chamber. The substrate support has a support surface configured to support a semiconductor substrate. The focus ring movement assembly is disposed in the internal volume of the chamber. The focus ring movement assembly includes a frame and a plurality of segment supports mechanically coupled to the frame. Each segment support of the plurality of segment supports is configured to support a respective discrete segment of a focus ring. The focus ring includes a plurality of discrete segments. The focus ring movement assembly is configured to support the plurality of discrete segments disposed laterally encircling the support surface. The focus ring movement assembly is configured to tilt the plurality of segment supports around respective axes, and each axis of the respective axes is parallel to the support surface.

In the processing tool of the second embodiment, the focus ring movement assembly may further include a drive motor that includes a drive shaft, and a plurality of lift pins. Each lift pin of the plurality of lift pins may be mechanically coupled to the drive shaft and may be configured to contact a respective discrete segment of the focus ring. The drive motor may be configured to cause movement of the drive shaft and the plurality of lift pins, and the movement of the drive shaft and the plurality of lift pins may cause the plurality of segment supports to be tilted around the respective axes.

In the processing tool of the second embodiment, the focus ring movement assembly may further be configured to translate the plurality of segment supports in respective directions. Each direction of the respective directions may be parallel to a respective radial direction that is in a plane of the support surface and from a center of the support surface.

In the processing tool of the second embodiment, the focus ring movement assembly may further be configured to translate the plurality of segment supports in respective directions parallel to a direction normal to the support surface.

The processing tool of the second embodiment may further include a plurality of focus ring electrical connectors. Each focus ring electrical connector of the plurality of the focus ring electrical connectors may be configured to electrically connect to and supply a voltage to an electrode of a respective discrete segment of the focus ring.

The processing tool of the second embodiment may further include a plurality of focus ring electrical connectors. Each pair of focus ring electrical connectors of the plurality of the focus ring electrical connectors may be configured to electrically connect to and supply a current to a resistive thermal element of a respective discrete segment of the focus ring.

The processing tool of the second embodiment may further include a power supply and a plurality of control circuits. The power supply may be configured to output a voltage on an output node of the power supply. Each control circuit of the plurality of control circuits may have an input node electrically coupled to the output node of the power supply and may have an output node configured to be electrically coupled to a respective discrete segment of the focus ring. Each control circuit of the plurality of control circuits may be controllable to adjust an amplitude, a phase, or a combination thereof of the voltage and output a corresponding adjusted voltage on the output node of the respective control circuit. Additionally, the processing tool may further include a controller. The controller may include one or more processors and non-transitory memory. The non-transitory memory may include stored instructions, which when executed by the one or more processors, may cause the one or more processors to control the plurality of control circuits to adjust the respective amplitude, the respective phase, or combination thereof.

A third embodiment is a method for semiconductor processing. The method includes moving a plurality of ring segments of a focus ring to respective positions relative to a semiconductor substrate. The semiconductor substrate is disposed on a support surface of a substrate support. The substrate support is disposed in a chamber of a processing tool. The plurality of ring segments of the focus ring laterally encircle the semiconductor substrate. Moving the plurality of ring segments includes translating the plurality of ring segments in respective first directions. Each first direction of the respective first directions is parallel to a respective radial direction that is in a plane of the support surface and from a center of the support surface. The method includes generating plasma in a processing volume of the chamber. The semiconductor substrate is exposed to the plasma while the plurality of ring segments are at the respective positions relative to the semiconductor substrate.

In the third embodiment, moving the plurality of ring segments may further include tilting the plurality of ring segments around respective axes. Each axis of the respective axes may be parallel to the support surface.

In the third embodiment, moving the plurality of ring segments may further include translating the plurality of ring segments in respective second directions parallel to a direction normal to the support surface.

The third embodiment may further include providing a respective current to each ring segment of the plurality of ring segments. Each ring segment of the plurality of ring segments may include a resistive heating element. The respective current may flow through the resistive heating element.

The method of the third embodiment may further include applying a respective voltage to each ring segment of the plurality of ring segments. Each ring segment of the plurality of ring segments may include a segment electrode.

A fourth embodiment is a method for semiconductor processing. The method includes moving a plurality of ring segments of a focus ring to respective positions relative to a semiconductor substrate. The semiconductor substrate is disposed on a support surface of a substrate support. The substrate support is disposed in a chamber of a processing tool. The plurality of ring segments of the focus ring laterally encircle the semiconductor substrate. Moving the plurality of ring segments includes tilting the plurality of ring segments around respective axes. Each axis of the axes is parallel to the support surface. The method includes generating plasma in a processing volume of the chamber. The semiconductor substrate is exposed to the plasma while the plurality of ring segments are at the respective positions relative to the semiconductor substrate.

In the fourth embodiment, moving the plurality of ring segments further may include translating the plurality of ring segments in respective directions parallel to a direction normal to the support surface.

The method of the fourth embodiment may further include providing a respective current to each ring segment of the plurality of ring segments. Each ring segment of the plurality of ring segments may include a resistive heating element. The respective current may flow through the resistive heating element.

The method of the fourth embodiment may further include applying a respective voltage to each ring segment of the plurality of ring segments. Each ring segment of the plurality of ring segments may include a segment electrode.

A fifth embodiment is a method for semiconductor processing. The method includes performing plasma semiconductor process having first process conditions on a first plurality of substrates using a processing tool. A plurality of discrete segments of a focus ring laterally encircle a substrate during the plasma semiconductor process. The first process conditions correspond to respective positions of the plurality of discrete segments disposed at respective first radial distances from a substrate during the plasma semiconductor process on the first plurality of substrates. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristics are formed by the plasma semiconductor process. The method includes, by a processor-based system, determining second process conditions to be applied while performing the plasma semiconductor process on a second plurality of substrates based on the first characteristics and the second characteristics. The second process conditions correspond to respective positions of the plurality of discrete segments disposed at respective second radial distances from a substrate during the plasma semiconductor process on the second plurality of semiconductor substrates. The method includes performing the plasma semiconductor process having the second process conditions on the second plurality of substrates using the processing tool.

In the fifth embodiment, the first process conditions may further correspond to respective positions of the plurality of discrete segments disposed at respective tilt angles relative to a top surface of a substrate during the plasma semiconductor process on the first plurality of substrates, and the second process conditions may further correspond to respective positions of the plurality of discrete segments disposed at respective tilt angles relative to a top surface of a substrate during the plasma semiconductor process on the second plurality of substrates.

In the fifth embodiment, the first process conditions may further correspond to respective positions of the plurality of discrete segments disposed at respective vertical positions relative to a substrate during the plasma semiconductor process on the first plurality of substrates, and the second process conditions may further correspond to respective positions of the plurality of discrete segments disposed at respective vertical positions relative to a substrate during the plasma semiconductor process on the second plurality of substrates.

In the fifth embodiment, the first characteristics may include, for each substrate of the first plurality of substrates, a first profile angle of a recess etched into the respective substrate proximate a respective center of the respective substrate, and the second characteristics may include, for each substrate of the first plurality of substrates, a second profile angle of a recess etched into the respective substrate proximate a respective edge of the respective substrate.

In the fifth embodiment, the first characteristics may include, for each substrate of the first plurality of substrates, a first depth of a recess etched into the respective substrate proximate a respective center of the respective substrate, and the second characteristics may include, for each substrate of the first plurality of substrates, a second depth of a recess etched into the respective substrate proximate a respective edge of the respective substrate.

In the fifth embodiment, the first characteristics may include, for each substrate of the first plurality of substrates, a first thickness of a film deposited on the respective substrate proximate a respective center of the respective substrate, and the second characteristics may include, for each substrate of the first plurality of substrates, a second thickness of the film proximate a respective edge of the respective substrate.

A sixth embodiment is a method for semiconductor processing. The method includes performing plasma semiconductor process having first process conditions on a first plurality of substrates using a processing tool. A plurality of discrete segments of a focus ring laterally encircle a substrate during the plasma semiconductor process. The first process conditions correspond to respective positions of the plurality of discrete segments disposed at respective tilt angles relative to a top surface of a substrate during the plasma semiconductor process on the first plurality of substrates. The method includes measuring respective first characteristics of the first plurality of substrates proximate to respective centers of the first plurality of substrates. The first characteristics are formed by the plasma semiconductor process. The method includes measuring respective second characteristics of the first plurality of substrates proximate to respective edges of the first plurality of substrates. The second characteristics are formed by the plasma semiconductor process. The method includes by a processor-based system, determining second process conditions to be applied while performing the plasma semiconductor process on a second plurality of substrates based on the first characteristics and the second characteristics. The second process conditions correspond to respective positions of the plurality of discrete segments disposed at respective tilt angles relative to a top surface of a substrate during the plasma semiconductor process on the second plurality of substrates. The method includes performing the plasma semiconductor process having the second process conditions on the second plurality of substrates using the processing tool.

In the sixth embodiment, the first process conditions may further correspond to respective positions of the plurality of discrete segments disposed at respective vertical positions relative to a substrate during the plasma semiconductor process on the first plurality of substrates, and the second process conditions may further correspond to respective positions of the plurality of discrete segments disposed at respective vertical positions relative to a substrate during the plasma semiconductor process on the second plurality of substrates.

In the sixth embodiment, the first characteristics may include, for each substrate of the first plurality of substrates, a first profile angle of a recess etched into the respective substrate proximate a respective center of the respective substrate, and the second characteristics may include, for each substrate of the first plurality of substrates, a second profile angle of a recess etched into the respective substrate proximate a respective edge of the respective substrate.

In the sixth embodiment, the first characteristics may include, for each substrate of the first plurality of substrates, a first depth of a recess etched into the respective substrate proximate a respective center of the respective substrate, and the second characteristics may include, for each substrate of the first plurality of substrates, a second depth of a recess etched into the respective substrate proximate a respective edge of the respective substrate.

In the method of the sixth embodiment, the first characteristics may include, for each substrate of the first plurality of substrates, a first thickness of a film deposited on the respective substrate proximate a respective center of the respective substrate, and the second characteristics may include, for each substrate of the first plurality of substrates, a second thickness of the film proximate a respective edge of the respective substrate.

Although various examples have been described in detail, it should be understood that various changes, substitutions, and alterations can be made therein without departing from the scope defined by the appended claims.

What is claimed is:

1. A processing tool for semiconductor processing, the processing tool comprising:
a chamber;
a substrate support disposed in the chamber, the substrate support having a support surface configured to support a semiconductor substrate; and
a focus ring movement assembly disposed in the chamber, the focus ring movement assembly comprising a frame and a plurality of segment supports mechanically coupled to the frame, each segment support of the plurality of segment supports being configured to support a respective discrete segment of a focus ring, the focus ring comprising a plurality of discrete segments, the focus ring movement assembly being configured to support the plurality of discrete segments disposed laterally encircling the support surface, and to translate the plurality of segment supports in respective first directions, each first direction of the respective first directions being parallel to a respective radial direction from a center of the support surface that is in a plane of the support surface.

2. The processing tool of claim 1, wherein:
the frame comprises a plurality of lateral translation guide tracks, each segment support of the plurality of segment supports being mechanically coupled to a respective lateral translation guide track of the plurality of lateral translation guide tracks, the respective segment support being configured to be laterally translated along the respective lateral translation guide track; and
the focus ring movement assembly further comprises:
a drive motor comprising a drive shaft; and
a plurality of linkages, each linkage having a first end mechanically coupled to a respective segment support of the plurality of segment supports and having a second end mechanically coupled to the drive shaft, wherein the drive motor is configured to move the drive shaft and the plurality of linkages, the movement of the drive shaft and the plurality of linkages causing the plurality of segment supports to be translated in the respective first directions.

3. The processing tool of claim 1, wherein the focus ring movement assembly is further configured to tilt the plurality of segment supports around respective axes, each axis of the respective axes being parallel to the support surface.

4. The processing tool of claim 1, wherein the focus ring movement assembly is further configured to translate the plurality of segment supports in respective second directions parallel to a direction normal to the support surface.

5. The processing tool of claim 1 further comprising a plurality of focus ring electrical connectors, each focus ring electrical connector of the plurality of the focus ring electrical connectors being configured to electrically connect to and supply a voltage to an electrode of a respective discrete segment of the focus ring.

6. The processing tool of claim 1 further comprising a plurality of focus ring electrical connectors, each pair of focus ring electrical connectors of the plurality of the focus ring electrical connectors being configured to electrically connect to and supply a current to a resistive thermal element of a respective discrete segment of the focus ring.

7. The processing tool of claim 1 further comprising:
a power supply configured to output a voltage on an output node of the power supply; and
a plurality of control circuits, each control circuit of the plurality of control circuits having an input node electrically coupled to the output node of the power supply and having an output node configured to be electrically coupled to a respective discrete segment of the focus ring, each control circuit of the plurality of control circuits being controllable to adjust an amplitude, a phase, or a combination of the voltage and output a corresponding adjusted voltage on the output node of the respective control circuit.

8. The processing tool of claim 7 further comprising:
a controller comprising:
one or more processors; and
non-transitory memory comprising stored instructions, which when executed by the one or more processors, cause the one or more processors to control the plurality of control circuits to adjust the respective amplitude, the respective phase, or a combination thereof.

9. A processing tool for semiconductor processing, the processing tool comprising:
a chamber;
a substrate support disposed in the chamber, the substrate support having a support surface configured to support a semiconductor substrate; and
a focus ring movement assembly disposed in the chamber, the focus ring movement assembly comprising a frame and a plurality of segment supports mechanically coupled to the frame, each segment support of the plurality of segment supports being configured to support a respective discrete segment of a focus ring, the focus ring comprising a plurality of discrete segments, the focus ring movement assembly being configured to support the plurality of discrete segments disposed laterally encircling the support surface, and to tilt the plurality of segment supports around respective axes, each axis of the respective axes being parallel to the support surface.

10. The processing tool of claim 9, wherein the focus ring movement assembly further comprises:
a drive motor comprising a drive shaft; and
a plurality of lift pins, each lift pin being mechanically coupled to the drive shaft and being configured to contact a respective discrete segment of the focus ring, wherein the drive motor is configured to move the drive shaft and the plurality of lift pins, the movement of the drive shaft and the plurality of lift pins causing the plurality of segment supports to be tilted around the respective axes.

11. The processing tool of claim 9, wherein the focus ring movement assembly is further configured to translate the plurality of segment supports in respective directions, each direction of the respective directions being parallel to a respective radial direction that is in a plane of the support surface and from a center of the support surface.

12. The processing tool of claim 9, wherein the focus ring movement assembly is further configured to translate the plurality of segment supports in respective directions parallel to a direction normal to the support surface.

13. The processing tool of claim 9 further comprising a plurality of focus ring electrical connectors, each focus ring electrical connector of the plurality of the focus ring electrical connectors being configured to electrically connect to and supply a voltage to an electrode of a respective discrete segment of the focus ring.

14. The processing tool of claim 9 further comprising a plurality of focus ring electrical connectors, each pair of focus ring electrical connectors of the plurality of the focus ring electrical connectors being configured to electrically connect to and supply a current to a resistive thermal element of a respective discrete segment of the focus ring.

15. The processing tool of claim 9 further comprising:
a power supply configured to output a voltage on an output node of the power supply; and
a plurality of control circuits, each control circuit of the plurality of control circuits having an input node electrically coupled to the output node of the power supply and having an output node configured to be electrically coupled to a respective discrete segment of the focus ring, each control circuit of the plurality of control circuits being controllable to adjust an amplitude, a phase, or a combination thereof of the voltage and output a corresponding adjusted voltage on the output node of the respective control circuit.

16. The processing tool of claim 15 further comprising:
a controller comprising:
one or more processors; and
non-transitory memory comprising stored instructions, which when executed by the one or more processors, cause the one or more processors to control the plurality of control circuits to adjust the respective amplitude, the respective phase, or combination thereof.

17. A method for semiconductor processing, the method comprising:
moving a plurality of ring segments of a focus ring to respective positions relative to a semiconductor substrate, the semiconductor substrate being disposed on a support surface of a substrate support, the substrate support being disposed in a chamber of a processing tool, the plurality of ring segments of the focus ring laterally encircling the semiconductor substrate, moving the plurality of ring segments comprising translating the plurality of ring segments in respective first directions, each first direction of the respective first directions being parallel to a respective radial direction that is in a plane of the support surface and from a center of the support surface; and
generating plasma in the chamber, the semiconductor substrate being exposed to the plasma while the plurality of ring segments are at the respective positions relative to the semiconductor substrate.

18. The method of claim 17, wherein moving the plurality of ring segments further comprises tilting the plurality of ring segments around respective axes, each axis of the respective axes being parallel to the support surface.

19. The method of claim 17, wherein moving the plurality of ring segments further comprises translating the plurality of ring segments in respective second directions parallel to a direction normal to the support surface.

20. The method of claim 17 further comprising providing a respective current to each ring segment of the plurality of ring segments, each ring segment of the plurality of ring segments comprising a resistive heating element, the respective current flowing through the resistive heating element.

21. The method of claim 17 further comprising applying a respective voltage to each ring segment of the plurality of ring segments, each ring segment of the plurality of ring segments comprising a segment electrode.

22. A method for semiconductor processing, the method comprising:
moving a plurality of ring segments of a focus ring to respective positions relative to a semiconductor substrate, the semiconductor substrate being disposed on a support surface of a substrate support, the substrate support being disposed in a chamber of a processing tool, the plurality of ring segments of the focus ring laterally encircling the semiconductor substrate, moving the plurality of ring segments comprising tilting the plurality of ring segments around respective axes, each axis of the axes being parallel to the support surface; and
generating plasma in the chamber, the semiconductor substrate being exposed to the plasma while the plurality of ring segments are at the respective positions relative to the semiconductor substrate.

23. The method of claim 22, wherein moving the plurality of ring segments further comprises translating the plurality of ring segments in respective directions parallel to a direction normal to the support surface.

24. The method of claim 22 further comprising providing a respective current to each ring segment of the plurality of ring segments, each ring segment of the plurality of ring segments comprising a resistive heating element, the respective current flowing through the resistive heating element.

25. The method of claim 22 further comprising applying a respective voltage to each ring segment of the plurality of ring segments, each ring segment of the plurality of ring segments comprising a segment electrode.

26. A method for semiconductor processing, the method comprising:
performing a plasma semiconductor process having first process conditions on a first plurality of substrates using a processing tool, wherein a plurality of discrete segments of a focus ring laterally encircle a substrate during the plasma semiconductor process, the first process conditions corresponding to respective positions of the plurality of discrete segments disposed at respective first radial distances from a substrate during the plasma semiconductor process on the first plurality of substrates;
measuring respective first characteristics of the first plurality of substrates proximate to respective centers of the first plurality of substrates, the first characteristics being formed by the plasma semiconductor process;
measuring respective second characteristics of the first plurality of substrates proximate to respective edges of the first plurality of substrates, the second characteristics being formed by the plasma semiconductor process;
determining, by a processor-based system, second process conditions to be applied while performing the plasma semiconductor process on a second plurality of substrates based on the first characteristics and the second characteristics, the second process conditions corresponding to respective positions of the plurality of discrete segments disposed at respective second radial distances from a substrate during the plasma semiconductor process on the second plurality of semiconductor substrates; and
performing the plasma semiconductor process having the second process conditions on the second plurality of substrates using the processing tool.

27. The method of claim 26, wherein:
the first process conditions further correspond to respective positions of the plurality of discrete segments disposed at respective tilt angles relative to a top surface of a substrate during the plasma semiconductor process on the first plurality of substrates; and
the second process conditions further correspond to respective positions of the plurality of discrete segments disposed at respective tilt angles relative to a top surface of a substrate during the plasma semiconductor process on the second plurality of substrates.

28. The method of claim 26, wherein:
the first process conditions further correspond to respective positions of the plurality of discrete segments disposed at respective vertical positions relative to a substrate during the plasma semiconductor process on the first plurality of substrates; and
the second process conditions further correspond to respective positions of the plurality of discrete segments disposed at respective vertical positions relative to a substrate during the plasma semiconductor process on the second plurality of substrates.

29. The method of claim 26, wherein:
the first characteristics include, for each substrate of the first plurality of substrates, a first profile angle of a recess etched into the respective substrate proximate a respective center of the respective substrate; and
the second characteristics include, for each substrate of the first plurality of substrates, a second profile angle of a recess etched into the respective substrate proximate a respective edge of the respective substrate.

30. The method of claim 26, wherein:
the first characteristics include, for each substrate of the first plurality of substrates, a first depth of a recess etched into the respective substrate proximate a respective center of the respective substrate; and
the second characteristics include, for each substrate of the first plurality of substrates, a second depth of a recess etched into the respective substrate proximate a respective edge of the respective substrate.

31. The method of claim 26, wherein:
the first characteristics include, for each substrate of the first plurality of substrates, a first thickness of a film deposited on the respective substrate proximate a respective center of the respective substrate; and
the second characteristics include, for each substrate of the first plurality of substrates, a second thickness of the film proximate a respective edge of the respective substrate.

32. A method for semiconductor processing, the method comprising:
performing a plasma semiconductor process having first process conditions on a first plurality of substrates using a processing tool, wherein a plurality of discrete segments of a focus ring laterally encircle a substrate during the plasma semiconductor process, the first process conditions corresponding to respective positions of the plurality of discrete segments disposed at respective tilt angles relative to a top surface of a substrate during the plasma semiconductor process on the first plurality of substrates;
measuring respective first characteristics of the first plurality of substrates proximate to respective centers of the first plurality of substrates, the first characteristics being formed by the plasma semiconductor process;
measuring respective second characteristics of the first plurality of substrates proximate to respective edges of the first plurality of substrates, the second characteristics being formed by the plasma semiconductor process;
by a processor-based system, determining second process conditions to be applied while performing the plasma semiconductor process on a second plurality of substrates based on the first characteristics and the second characteristics, the second process conditions corresponding to respective positions of the plurality of discrete segments disposed at respective tilt angles relative to a top surface of a substrate during the plasma semiconductor process on the second plurality of substrates; and
performing the plasma semiconductor process having the second process conditions on the second plurality of substrates using the processing tool.

33. The method of claim 32, wherein:
the first process conditions further correspond to respective positions of the plurality of discrete segments disposed at respective vertical positions relative to a substrate during the plasma semiconductor process on the first plurality of substrates; and
the second process conditions further correspond to respective positions of the plurality of discrete segments disposed at respective vertical positions relative to a substrate during the plasma semiconductor process on the second plurality of substrates.

34. The method of claim 32, wherein:
the first characteristics include, for each substrate of the first plurality of substrates, a first profile angle of a recess etched into the respective substrate proximate a respective center of the respective substrate; and
the second characteristics include, for each substrate of the first plurality of substrates, a second profile angle of a recess etched into the respective substrate proximate a respective edge of the respective substrate.

35. The method of claim 32, wherein:
the first characteristics include, for each substrate of the first plurality of substrates, a first depth of a recess etched into the respective substrate proximate a respective center of the respective substrate; and
the second characteristics include, for each substrate of the first plurality of substrates, a second depth of a recess etched into the respective substrate proximate a respective edge of the respective substrate.

36. The method of claim 32, wherein:
the first characteristics include, for each substrate of the first plurality of substrates, a first thickness of a film deposited on the respective substrate proximate a respective center of the respective substrate; and
the second characteristics include, for each substrate of the first plurality of substrates, a second thickness of the film proximate a respective edge of the respective substrate.
